(19) United States
(12) Patent Application Publication
(10) Pub. No.: US 2025/0357442 A1
(43) Pub. Date: Nov. 20, 2025

(54) SEMICONDUCTOR PACKAGE AND MANUFACTURING METHOD THEREOF

(71) Applicant: Samsung Electronics Co., Ltd., Suwon-si (KR)

(72) Inventors: Hyeonjeong HWANG, Suwon-si (KR); Jihwang KIM, Suwon-si (KR)

(73) Assignee: Samsung Electronics Co., Ltd., Suwon-si (KR)

(21) Appl. No.: 18/968,342

(22) Filed: Dec. 4, 2024

(30) Foreign Application Priority Data
May 20, 2024 (KR) 10-2024-0065361

(51) Int. Cl. H01L 25/10; H01L 23/00; H01L 23/373; H01L 23/498; H01L 25/00

(52) U.S. Cl. CPC H01L 25/105; H01L 23/373; H01L 24/24; H01L 24/25; H01L 25/50; H01L 23/49816; H01L 2224/24146; H01L 2224/2518; H01L 2225/1094

(57) ABSTRACT

The semiconductor package includes a first redistribution substrate, a first semiconductor chip on a first side the first redistribution substrate, a first through-post on a second side of the first redistribution substrate, a second redistribution substrate on the first semiconductor chip and the first through-post, a second semiconductor chip on a second side of the second redistribution substrate, a second through-post on a first side of the second redistribution substrate, a third redistribution substrate on the second semiconductor chip and the second through-post, a heat dissipation block on a second side of the third redistribution substrate, and a semiconductor device on a first side of the third redistribution substrate. The first side of the first redistribution substrate, the second redistribution substrate, and the third redistribution substrate, are each spaced apart from a respective second side in a horizontal direction and the first sides are each aligned in a vertical direction.

### CROSS-REFERENCE TO RELATED APPLICATION

This application is based on and claims priority under 35 USC § 119 to Korean Patent Application No. 10-2024-0065361, filed on May 20, 2024, in the Korean Intellectual Property Office, the disclosure of which is incorporated by reference herein in its entirety.

### BACKGROUND

The inventive concepts relate to semiconductor packages, and more particularly, to semiconductor packages including two logic chips and manufacturing methods thereof.

In accordance with the rapid development of the electronics industry and user demands, electronic devices have become smaller and lighter. As electronic devices have become smaller and lighter, semiconductor packages used therein have also become smaller and lighter and have been required to have high reliability along with high performance and high capacity. As semiconductor packages have had higher performance and higher capacity, power consumption of semiconductor packages has increased. Accordingly, the importance of reducing the size and improving the performance of semiconductor packages and the heat dissipation characteristics of semiconductor packages has increased.

### SUMMARY

The inventive concepts provide semiconductor packages capable of implementing a small form factor, maximizing or otherwise improving heat dissipation characteristics, and improving reliability, and manufacturing methods thereof.

In addition, the problems to be solved by the technical idea of the inventive concepts are not limited to the problems mentioned above, and other problems may be clearly understood by those skilled in the art from the description below.

According to aspects of the inventive concepts, there is provided a semiconductor package comprising including a first redistribution substrate having a first side and a second side spaced apart in a first horizontal direction; a first semiconductor chip on the first side of the first redistribution substrate; a first through-post on the second side of the of the first redistribution substrate; a second redistribution substrate on the first semiconductor chip and the first through-post, the second redistribution substrate having a first side and a second side spaced apart in the first horizontal direction; a second semiconductor chip on the second side of the second redistribution substrate; a second through-post on the first side of the second redistribution substrate; a third redistribution substrate on the second semiconductor chip and the second through-post, the third redistribution substrate having a first side and a second side spaced apart in the first horizontal direction, the first side of the first redistribution substrate, the first side of the second redistribution substrate, and the first side of the third redistribution substrate being aligned in a vertical direction perpendicular to an upper surface of the first redistribution substrate; a heat dissipation block on the second side of the third redistribution substrate; and a semiconductor device on the first side of the third redistribution substrate.

According to other aspects of the inventive concepts, there is provided a semiconductor package including a first redistribution substrate having a first side and a second side spaced apart in a first horizontal direction; a first semiconductor chip on the first side of the first redistribution substrate; a first through-post on the second side of the first redistribution substrate; a second through-post on the first semiconductor chip; a second semiconductor chip on the first through-post; a second redistribution substrate on the second semiconductor chip and the second through-post, the second redistribution substrate having a first side and a second side spaced apart in the first horizontal direction, the first side of the second redistribution substrate and the first side of the first redistribution substrate are aligned in a vertical direction perpendicular to an upper surface of the first redistribution substrate; a heat dissipation block on the second side of the second redistribution substrate; a semiconductor device on the first side of the second redistribution substrate; a sealant located between the first redistribution substrate and the second redistribution substrate and covering side surfaces of the first through-post and the second through-post, a side surface and an upper surface of the first semiconductor chip, and a side surface and a lower surface of the second semiconductor chip; and an external connection terminal on a lower surface of the first redistribution substrate.

According to other aspects of the inventive concepts, there is provided a semiconductor package including a first redistribution substrate having a first side and a second side spaced apart in a first horizontal direction; a first semiconductor chip on the first side of the first redistribution substrate; a first through-post on the second side of the first redistribution substrate; a second through-post on the first semiconductor chip; a second semiconductor chip on the first through-post; a second redistribution substrate on the second semiconductor chip and the second through-post, the second redistribution substrate having a first side and a second side spaced apart in the first horizontal direction, the first side of the second redistribution substrate and the first side of the first redistribution substrate are aligned in a vertical direction perpendicular to an upper surface of the first redistribution substrate; a heat dissipation block on the second side of the second redistribution substrate; a semiconductor device on the first side of the second redistribution substrate; and a sealant located between the first redistribution substrate and the second redistribution substrate.

According to other aspects of the inventive concepts, there is provided a method of manufacturing a semiconductor package including forming a first redistribution substrate having a first side and a second side spaced apart in a first horizontal direction; forming a first through-post on the second side of the first redistribution substrate; disposing a first semiconductor chip on the second side of the first redistribution substrate; forming a second redistribution substrate on the first through-post and the first semiconductor chip, the second redistribution substrate having a first side and a second side spaced apart in the first horizontal direction; forming a second through-post on the first side of the second redistribution substrate; disposing a second semiconductor chip on the second side of the second redistribution substrate; forming a third redistribution substrate on the second semiconductor chip and the second through-post, the third redistribution substrate having a first side and a second side spaced apart in the first horizontal direction, the first side of the first redistribution substrate, the first side of the second redistribution substrate, and the first side of the third redistribution substrate being aligned in a vertical direction perpendicular to an upper surface of the first redistribution substrate; and disposing a heat dissipation block on the second side of the third redistribution substrate, and disposing a semiconductor device on the first side of the third redistribution substrate.

According to other aspects of the inventive concepts, there is provided a method of manufacturing a semiconductor package including forming a first redistribution substrate having a first side and a second side spaced apart in a first horizontal direction; forming a first through-post on the second side of the first redistribution substrate; disposing a first semiconductor chip on the first side of the first redistribution substrate; forming a lower sealant covering a side surface of the first through-post and a side surface and an upper surface of the first semiconductor chip; forming a second through-post on the first semiconductor chip; disposing a second semiconductor chip on the first through-post and the lower sealant; forming an upper sealant covering a side surface of the second through-post and a side surface and a lower surface of the second semiconductor chip; forming a second redistribution substrate on the second semiconductor chip and the upper sealant, the second redistribution substrate having a first side and a second side spaced apart in the first horizontal, the first side of the second redistribution substrate being aligned in a vertical direction with the first side of the first redistribution substrate; and disposing a heat dissipation block on the second side of the second redistribution substrate and disposing a semiconductor device on the first side of the second redistribution substrate.

### BRIEF DESCRIPTION OF THE DRAWINGS

Example embodiments will be more clearly understood from the following detailed description taken in conjunction with the accompanying drawings in which:

FIG. 1 is a cross-sectional view of a semiconductor package, according to some example embodiments;

FIGS. 2A to 2C are cross-sectional views illustrating a structure of a semiconductor device in the semiconductor package of FIG. 1 in detail;

FIGS. 3A to 3C are cross-sectional views of semiconductor packages according to some example embodiments;

FIGS. 4A and 4B are cross-sectional views of semiconductor packages according to some example embodiments;

FIGS. 5A and 5B are cross-sectional views of semiconductor packages according to some example embodiments;

FIGS. 6A to 6N are cross-sectional views schematically illustrating a process of a method of manufacturing a semiconductor package according to some example embodiments;

FIGS. 7A to 7E are cross-sectional views illustrating an operation of FIG. 6C in detail; and

FIGS. 8A to 8D are cross-sectional views schematically illustrating a process of a method of manufacturing a semiconductor package according to some example embodiments.

### DETAILED DESCRIPTION

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Hereinafter, some example embodiments are described in detail with reference to the accompanying drawings. The same reference numerals are used for the same components in the drawings, and redundant descriptions thereof are omitted.

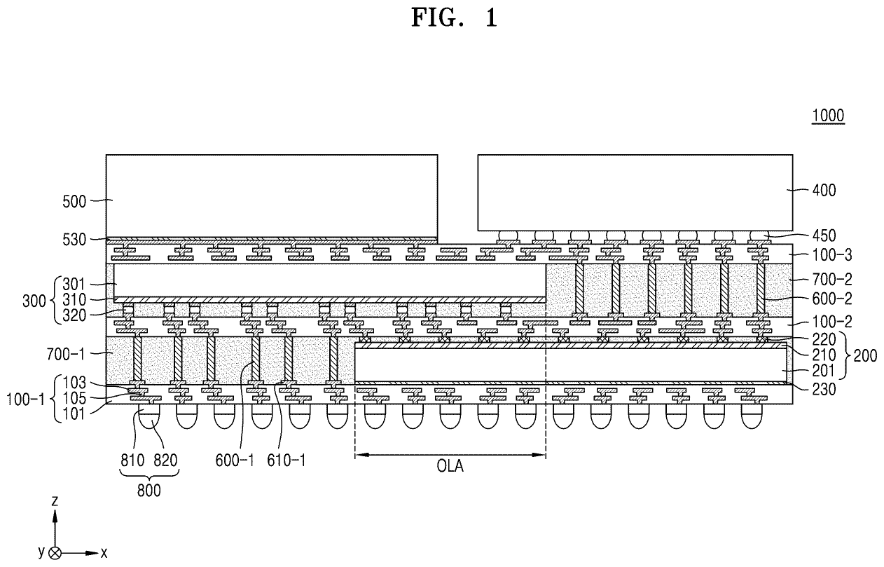

FIG. 1 is a cross-sectional view of a semiconductor package 1000 according to some example embodiments.

Referring to FIG. 1, the semiconductor package 1000 of the present example embodiments includes first to third redistribution substrates 100-1 to 100-3, a first semiconductor chip 200, a second semiconductor chip 300, a semiconductor device 400, a heat dissipation block 500, first and second through-posts 600-1 and 600-2, first and second sealants 700-1 and 700-2, and an external connection terminal 800.

The first redistribution substrate 100-1 may be disposed below the first semiconductor chip 200, the first through-post 600-1, and the first sealant 700-1. The first redistribution substrate 100-1 may redistribute chip pads of the first semiconductor chip 200 to an external region of the first semiconductor chip 200. The first redistribution substrate 100-1 may include a body insulating layer 101, a redistribution line 103, and a vertical via 105.

The body insulating layer 101 may be formed of an insulating material, for example, a photo imageable dielectric (PID) or photo imageable polyimide (PIP) resin, and may further include an inorganic filler. However, the material of the body insulating layer 101 is not limited to the aforementioned materials. For example, the body insulating layer 101 may include polymide isoindro quirazorindione (PIQ), polyimide (PI), polybenzoxazole (PBO), etc.

The body insulating layer 101 may have a multi-layer structure according to a multi-layer structure of the redistribution line 103. However, in FIG. 1, for convenience, the body insulating layer 101 is shown as a single-layer structure. When the body insulating layer 101 has a multi-layer structure, all layers of the body insulating layer 101 may include the same material, or at least one layer may include a different material.

The redistribution line 103 may be arranged as a multi-layer within the body insulating layer 101. The redistribution lines 103 arranged on different layers may be connected to each other by the vertical via 105. Meanwhile, the redistribution lines 103 having a level difference of two or more layers may be connected to each other through stacking of a plurality of vertical vias 105. The stacked vertical vias 105 may be referred to as stacked vias. The redistribution line 103 and the vertical via 105 may include, for example, copper (Cu). However, the material of the redistribution line 103 and the vertical via 105 is not limited to Cu.

An external connection terminal 800 may be disposed on a lower surface of the body insulating layer 101. The external connection terminal 800 may be disposed on an external connection pad disposed on the lower surface of the body insulating layer 101. An external connection pad may be included as part of the redistribution line 103. However, in some embodiments, the external connection pad may be treated as a separate component from the redistribution line 103.

The first semiconductor chip 200 may be disposed on the first redistribution substrate 100-1 through an adhesive layer 230. The first semiconductor chip 200 may be disposed on the first redistribution substrate 100-1 to be biased to one side in an X-direction. For example, as shown in FIG. 1, the first semiconductor chip 200 may be disposed on the first redistribution substrate 100-1 to be biased to the right in the X-direction. For example, the first semiconductor chip 200 may be biased to a first side of the first redistribution substrate 100-1 in the X-direction such that a portion of an upper surface of the first redistribution substrate 100-1 is exposed (e.g., not overlapped in the vertical direction, Y direction) by the first semiconductor chip 200.

The first semiconductor chip 200 may be a logic chip. Accordingly, the first semiconductor chip 200 may include a plurality of logic devices therein. Here, the logic device is a device that performs various signal processing and may include, for example, an AND, an OR, a NOT, a flip-flop, etc. For example, the first semiconductor chip 200 may be a neural processing unit (NPU) chip. In some example embodiments, the first semiconductor chip 200 may be a modem chip that supports communication with the second semiconductor chip 300. However, the type of the first semiconductor chip 200 is not limited to an NPU chip or a modem chip. For example, the first semiconductor chip 200 may perform individual operations or may include various types of integrated devices to support the operation of the second semiconductor chip 300. The first semiconductor chip 200 may include a multi-channel input/output (I/O) interface for exchanging memory signals with the semiconductor device 400. In addition, the first semiconductor chip 200 may include static random-access memory (SRAM) for temporary storage of data.

As shown in FIG. 1, the first semiconductor chip 200 may include a substrate 201, an active layer 210, and a first connection terminal 220. The substrate 201 may constitute a body of the first semiconductor chip 200 and may be based on a silicon wafer. The active layer 210 may be disposed on the substrate 201. Strictly speaking, the active layer 210 may include an IC layer in which active elements, such as transistors, are disposed, and a multi-interconnection layer disposed on the IC layer. Generally, the multi-interconnection layer occupies most of the active layer 210, and the IC layer may occupy only a portion of the active layer 210. Meanwhile, the multi-interconnection layer includes an interconnection line of a multi-layer, and interconnection lines of different layers may be connected to each other through vias. A chip pad connected to the interconnection line of the multi-interconnection layer may be disposed on an upper surface of the active layer 210, and the first connection terminal 220 may be disposed on the chip pad.

In the first semiconductor chip 200, an upper surface may be a front side, which is an active surface, and a lower surface may be a back side, which is an inactive surface. In other words, the upper surface of the active layer 210 may correspond to the front side of the first semiconductor chip 200, and the lower surface of the substrate 201 may correspond to the back side of the first semiconductor chip 200. The chip pad may be formed on the front side, which is the active surface, and the first connection terminal 220 may be disposed on the chip pad. The first connection terminal 220 may include a metal pillar or solder. In some example embodiments, the first connection terminal 220 may include a metal pillar and solder. Here, the metal pillar may include, for example, Cu. However, the material of the metal pillar is not limited to Cu. The first semiconductor chip 200 may be connected to the second redistribution substrate 100-2 through the first connection terminal 220.

The first through-post 600-1 may be located between the first redistribution substrate 100-1 and the second redistribution substrate 100-2. As the first sealant 700-1 is located between the first redistribution substrate 100-1 and the second redistribution substrate 100-2, the first through-post 600-1 may have a structure extending in a Z-direction through the first sealant 700-1. The first through-post 600-1 may electrically connect the first redistribution substrate 100-1 to the second redistribution substrate 100-2. For example, the first through-post 600-1 may be connected to the redistribution line 103 of the first redistribution substrate 100-1 and may also be connected to the redistribution line of the second redistribution substrate 100-2. For example, the first through-posts 600-1 may be on a second side of the first redistribution substrate 100-1 spaced apart for the first side in the X direction and exposed by the first semiconductor chip 200. For example, the first through-posts 600-1 may be on an upper surface of the first redistribution substrate 100-1 opposite the first semiconductor chip 200.

In the semiconductor package 1000 of the present example embodiments, the first through-post 600-1 may be disposed, for example, as a two-dimensional (2D) array structure on the left first redistribution substrate 100-1 of the first semiconductor chip 200 in the X-direction. The first through-post 600-1 may be connected to the second semiconductor chip 300 through the second redistribution substrate 100-2. In addition, the first through-post 600-1 may be connected to the semiconductor device 400 through the second redistribution substrate 100-2 and the second through-post 600-2.

The first through-post 600-1 may include, for example, Cu. Accordingly, the first through-post 600-1 may be referred to as a Cu post. However, the material of the first through-post 600-1 is not limited to Cu. The first through-post 600-1 may be formed through electroplating using a seed metal. The seed metal may include various metal materials, such as Cu, titanium (Ti), tantalum (Ta), titanium nitride (TiN), and/or tantalum nitride (TaN). In the semiconductor package 1000 of the present example embodiments, a lower pad 610-1 of the first redistribution substrate 100-1 may function as a seed metal. However, according to some example embodiments, the seed metal may be formed separately from the lower pad 610-1.

The second redistribution substrate 100-2 may be disposed on the first semiconductor chip 200, the first through-post 600-1, and the first sealant 700-1. The second redistribution substrate 100-2 may also include a body insulating layer, a redistribution line, and a vertical via. The second redistribution substrate 100-2 may have a similar structure to that of the first redistribution substrate 100-1 but may differ in thickness. For example, the number of layers of the redistribution line of the second redistribution substrate 100-2 may be less than the number of layers of the redistribution line 103 of the first redistribution substrate 100-1. However, in some example embodiments, the number of layers of the redistribution lines of the second redistribution substrate 100-2 may be substantially the same as the number of layers of the redistribution lines 103 of the first redistribution substrate 100-1. Meanwhile, the redistribution line of the second redistribution substrate 100-2 may be connected to the external connection terminal 800 through the first through-post 600-1 and the first redistribution substrate 100-1.

The second semiconductor chip 300 may be mounted on the second redistribution substrate 100-2 through the second connection terminal 320. The second semiconductor chip 300 may be disposed on the left of the second redistribution substrate 100-2 in the X-direction to correspond to the first through-post 600-1. In addition, the second semiconductor chip 300 and the first semiconductor chip 200 may at least partially overlap each other in a Z-direction. For example, the second semiconductor chip 300 may be biased to a second side of the second redistribution substrate 100-2 direction in the X-direction such that a portion of an upper surface of the second redistribution substrate 100-2 is exposed (e.g., not overlapped in the vertical direction, Y direction) by the second semiconductor chip 300. For example, the overlap region OLA in which the second semiconductor chip 300 and the first semiconductor chip 200 overlap each other may have an area less than 50% of the second semiconductor chip 300 and the first semiconductor chip 200. However, the area of the overlap region OLA is not limited to the above numerical range. The second semiconductor chip 300 is connected to the first semiconductor chip 200 using a portion of the second redistribution substrate 100-2 corresponding to the overlap region OLA, thereby minimizing or otherwise reducing a signal path between the first semiconductor chip 200 and the second semiconductor chip 300.

In some example embodiments, the second semiconductor chip 300 may also be mounted on the second redistribution substrate 100-2 through pad-to-pad bonding, hybrid bonding (HB), or bonding using an anisotropic conductive film (ACF). For reference, because the pad may include Cu, pad-to-pad bonding is also referred to as Cu-to-Cu bonding. HB may refer to a combination of pad-to-pad bonding and insulator-to-insulator bonding. ACF is an anisotropic conductive film that conducts electricity in only one direction and may refer to a conductive film formed by mixing fine conductive particles with an adhesive resin to form a film.

The second semiconductor chip 300 may be a logic chip. Accordingly, the second semiconductor chip 300 may include a plurality of logic devices therein. In the semiconductor package 1000 of the present example embodiments, the second semiconductor chip 300 may be, for example, an application processor (AP) chip. In addition, the second semiconductor chip 300 may be referred to as a control chip, a process chip, a central processing unit (CPU) chip, a graphics processing unit (GPU) chip, etc., depending on functions thereof. Meanwhile, in terms of integrated functionality, the second semiconductor chip 300 may be referred to as a system on chip (SoC) together with or independently of the first semiconductor chip 200.

The second semiconductor chip 300 may include a substrate 301, an active layer 310, and a second connection terminal 320. The active layer 310 may include an IC layer and a multi-interconnection layer. The IC layer may include multiple integrated devices. The multi-interconnection layer may be disposed below the IC layer and may include an interconnection line of a multi-layer. In the second semiconductor chip 300, a lower surface may be a front side, which is an active surface, and an upper surface may be a back side, which is an inactive surface. In other words, the lower surface of the active layer 310 may correspond to the front side of the second semiconductor chip 300, and the upper surface of the substrate 301 may correspond to the back side of the second semiconductor chip 300.

The second through-post 600-2 may be located between the second redistribution substrate 100-2 and the third redistribution substrate 100-3. As the second sealant 700-2 is located between the second redistribution substrate 100-2 and the third redistribution substrate 100-3, the second through-post 600-2 may have a structure that extends in the Z-direction through the second sealant 700-2. The second through-post 600-2 may connect the second redistribution substrate 100-2 to the third redistribution substrate 100-3. For example, the second through-post 600-2 may be connected to the redistribution line of the second redistribution substrate 100-2 and may also be connected to the redistribution line of the third redistribution substrate 100-3. For example, the second through-posts 600-2 may be on a first side of the second redistribution substrate 100-2 spaced apart from the second side and exposed by the second semiconductor chip 300. For example, the second through-posts 600-2 may be on an upper surface of the second redistribution substrate 100-2 opposite the second semiconductor chip 300.

In the semiconductor package 1000 of the present example embodiments, the second through-post 600-2 may be, for example, as a 2D array structure on the right side of second redistribution substrate 100-2 of the second semiconductor chip 300 in the X-direction. The second through-post 600-2 may be connected to the semiconductor device 400 through the third redistribution substrate 100-3. In addition, the second through-post 600-2 may be connected to the first semiconductor chip 200 and the second semiconductor chip 300 through the second redistribution substrate 100-2.

Meanwhile, in the semiconductor package 1000 of the present example embodiments, left and right in the X-direction may be relative concepts. Accordingly, the positions of the first semiconductor chip 200 and the first through-post 600-1 may change. For example, the first semiconductor chip 200 may be disposed to be biased to the left in the X-direction, and the first through-post 600-1 may be disposed on the right of the first semiconductor chip 200 in the X-direction. In addition, the second semiconductor chip 300 may be disposed on the right in the X-direction to correspond to the first through-post 600-1, and the second through-post 600-2 and the semiconductor device 400 may be disposed on the left in the X-direction.

The material or forming method of the second through-post 600-2 may be substantially the same as that of the first through-post 600-1. However, the number of first through-posts 600-1 may be greater than the number of second through-posts 600-2. For example, the number of first through-posts 600-1 may be 30% or more than the number of second through-posts 600-2 (e.g., between 30% more and 100% more). However, the difference in number between the first through-post 600-1 and the second through-post 600-2 is not limited to the aforementioned numerical range.

The third redistribution substrate 100-3 may be disposed on the second semiconductor chip 300, the second through-post 600-2, and the second sealant 700-2. The third redistribution substrate 100-3 may also include a body insulating layer, a redistribution line, and a vertical via. The third redistribution substrate 100-3 may have a similar structure to that of the first redistribution substrate 100-1 or the second redistribution substrate 100-2 but may have a different thickness. For example, the number of layers of the redistribution line of the third redistribution substrate 100-3 may be different from the number of layers of the redistribution line of the first redistribution substrate 100-1 or the second redistribution substrate 100-2. In detail, the number of layers of the redistribution line of the third redistribution substrate 100-3 may be less than the number of layers of the redistribution line 103 of the first redistribution substrate 100-1 and may be greater than the number of layers of the redistribution line of the second redistribution substrate 100-2. However, the number of layers of the redistribution line of the third redistribution substrate 100-3 is not limited to the above. Meanwhile, the redistribution line of the third redistribution substrate 100-3 may be connected to the first semiconductor chip 200 and the second semiconductor chip 300 through the second through-post 600-2 and the second redistribution substrate 100-2.

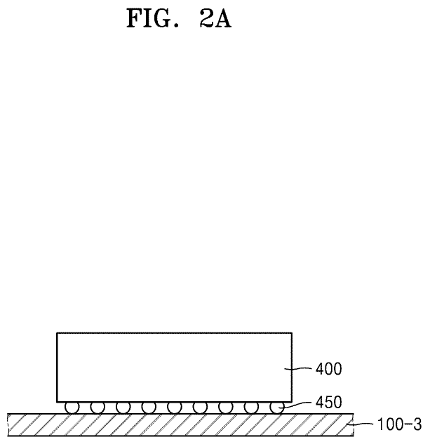

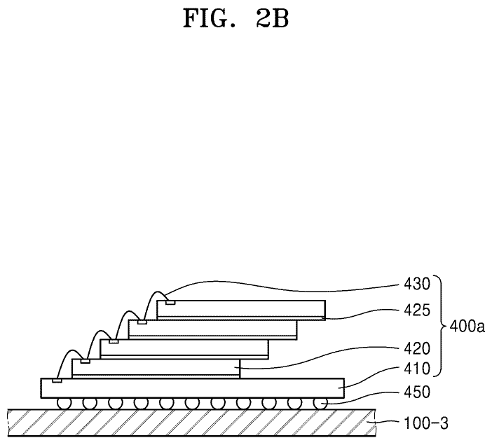

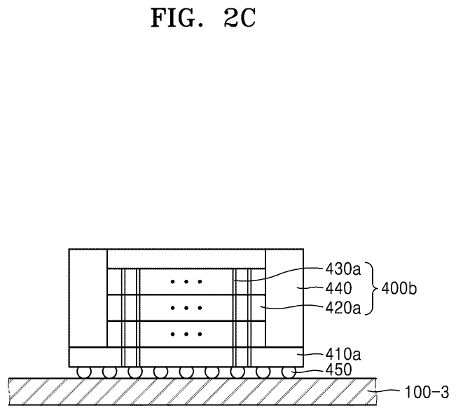

The semiconductor device 400 may be mounted on the third redistribution substrate 100-3 through a third connection terminal 450. The semiconductor device 400 may be disposed on the right on the third redistribution substrate 100-3 in the X-direction to correspond to the second through-post 600-2. For example, the semiconductor device 400 may be on a first side of the third redistribution substrate 100-3. The semiconductor device 400 may be a single chip or a package including a plurality of chips. For example, when the semiconductor device 400 is a single chip, the semiconductor device 400 may include one memory chip. When the semiconductor device 400 is a package, the semiconductor device 400 may include, for example, a plurality of memory chips. The memory chip of the semiconductor device 400 may include, for example, a volatile memory device, such as dynamic random access memory (DRAM) or static random access memory (SRAM), or a non-volatile memory device, such as flash memory. In the semiconductor package 1000 of the present example embodiments, the memory chip of the semiconductor device 400 may be, for example, a DRAM chip. However, the type of memory chip of the semiconductor device 400 is not limited to DRAM chips. A single chip structure or package structure of the semiconductor device 400 is described in detail below with reference to FIGS. 2A to 2C.

When the semiconductor device 400 is a package, the semiconductor package 1000 of the present example embodiments may have a package-on-package (POP) structure. For example, in the semiconductor package 1000 of the present example embodiments, the first to third redistribution substrates 100-1 to 100-3, the first and second semiconductor chips 200 and 300, and the first and second through-posts 600-1 and 600-2 may constitute a lower package, and the semiconductor device 400 of the package structure may constitute an upper package. Accordingly, the semiconductor package 1000 of the present example embodiments may have a POP structure in which an upper package is stacked on a lower package.

A heat dissipation block 500 may be mounted on the third redistribution substrate 100-3 through an adhesive layer 530. For example, the heat dissipation block 500 may be mounted on a second side of the third redistribution substrate 100-3 spaced apart in the X direction from the first side of the third redistribution substrate 100-3. The heat dissipation block 500 may be disposed on the left of the third redistribution substrate 100-3 in the X-direction to correspond to the second semiconductor chip 300. That is, the heat dissipation block 500 may be disposed on the left of the semiconductor device 400 in the X-direction on the third redistribution substrate 100-3. The heat dissipation block 500 may include, for example, a heatsink or a heatslug. According to some example embodiments, the heat dissipation block 500 may be referred to as a heat path block (HPB). Meanwhile, the adhesive layer 530 may include a material having high thermal conductivity. For example, the adhesive layer 530 may include thermal interface material (TIM) or thermally conductive resin. The TIM may include materials having high thermal conductivity, that is, low thermal resistance, such as grease, tape, an elastomer filling pad, and/or a phase transfer material.

In some example embodiments, the first side of the first redistribution substrate 100-1, the first side of the second redistribution substrate 100-2, and the first side of the third redistribution substrate 100-3 may be aligned in the vertical direction (Z direction). In some example embodiments, the second side of the first redistribution substate 100-2, the second side of the second redistribution substrate 100-2, and the third side of the third redistribution substrate 100-3 my be aligned in the vertical direction (Z direction).

The first sealant 700-1 may be located between the first redistribution substrate 100-1 and the second redistribution substrate 100-2. The first sealant 700-1 may cover and seal a side surface of the first through-post 600-1 and side and upper surfaces of the first semiconductor chip 200. In some example embodiments, the first semiconductor chip 200 may be connected to the second redistribution substrate 100-2 by pad-to-pad bonding, HB, bonding using ACF, etc., and the first sealant 700-1 may cover the side of the first semiconductor chip 200.

The second sealant 700-2 may be located between the second redistribution substrate 100-2 and the third redistribution substrate 100-3. The second sealant 700-2 may cover and seal a side surface of the second through-post 600-2 and side and lower surfaces of the second semiconductor chip 300. In some example embodiments, the second sealant 700-2 may cover the side surfaces of the second through-post 600-2 and the second semiconductor chip 300.

The first sealant 700-1 and the second sealant 700-2 may include an insulating material, for example, a thermosetting resin, such as an epoxy resin, a thermoplastic resin, such as polyimide, or a resin including a reinforcing material, such as an inorganic filler, mixed in these materials. For example, the first sealant 700-1 and the second sealant 700-2 may include Ajinomoto build-up film (ABF), flame retardant (FR)-4, bismaleimide triazine (BT) resin, etc. In addition, the first sealant 700-1 and the second sealant 700-2 may include a molding material, such as epoxy molding compound (EMC), or a photosensitive material, such as a photo imageable encapsulant (PIE). However, the materials of the first sealant 700-1 and the second sealant 700-2 are not limited to the aforementioned materials.

The external connection terminal 800 may be disposed on the lower surface of the first redistribution substrate 100-1. For example, an external connection pad may be disposed on the lower surface of the first redistribution substrate 100-1, and the external connection terminal 800 may be disposed on the external connection pad. The external connection terminal 800 may connect the semiconductor package 1000 to a package substrate of an external system or a main board of an electronic device, such as a mobile device. The external connection terminal 800 may be electrically connected to the redistribution line 103 of the first redistribution substrate 100-1 through an external connection pad. In addition, the external connection terminal 800 may be electrically connected to the first through-post 600-1 through the redistribution line 103 of the first redistribution substrate 100-1.

The external connection terminal 800 may include a metal pillar 810 and solder 820. The metal pillar 810 may include, for example, Cu. However, the material of the metal pillar 810 is not limited to Cu. In some example embodiments, the external connection terminal 800 may include only solder.

Meanwhile, as the external connection terminal 800 is disposed on the lower surface of the first redistribution substrate 100-1, the external connection terminal 800 may be disposed in a region larger than the area of the first semiconductor chip 200 or the second semiconductor chip 300. In this manner, a package structure in which the external connection terminal 800 is disposed in a region larger than the area of the first semiconductor chip 200 or the second semiconductor chip 300 is referred to as a fan-out (FO) package structure.

In the semiconductor package 1000 of the present example embodiments, for example, the first semiconductor chip 200 may have an area of 8.0*12.0 mm² or less, the second semiconductor chip 300 may have an area of 5.0*11.0 mm² or less, and the semiconductor device 400 may have an area of 7.0*13.0 mm² or less, and the overall area of the package may be 17.0*14.0 mm² or less. In addition, a pitch/width of each of the first connection terminal 220 of the first semiconductor chip 200 and the second connection terminal 320 of the second semiconductor chip 300 may be, for example, 90/50 μm or less. However, in the semiconductor package 1000 of the present example embodiments, the area of the components or the pitch/width of the connection terminals are not limited to the above numerical ranges.

As for the area and positional relationship of the first to third redistribution substrates 100-1 to 100-3, first and second semiconductor chips 200 and 300, first and second through-posts 600-1 and 600-2, and the semiconductor device 400 with reference to FIG. 1, each of the first to third redistribution substrates 100-1 to 100-3 may have substantially the same area as that of each the first and second sealants 700-1 and 700-2 in a plan view. Accordingly, the first semiconductor chip 200 and the first through-post 600-1 may be located in the first redistribution substrate 100-1 in a planar view. In addition, the second semiconductor chip 300 and the second through-post 600-2 may be located in the second redistribution substrate 100-2 in a plan view. Meanwhile, the semiconductor device 400 and the heat dissipation block 500 may be located in the third redistribution substrate 100-3 in a plan view.

The first semiconductor chip 200 and the second semiconductor chip 300 may at least partially overlap each other in the Z-direction. For example, the first semiconductor chip 200 and the second semiconductor chip 300 may overlap each other by 50% of less of their respective areas in the Z-direction. In addition, the heat dissipation block 500 may overlap the second semiconductor chip 300 in the Z-direction. For example, the heat dissipation block 500 may overlap the second semiconductor chip 300 to cover 70% or more of the area of the second semiconductor chip 300. However, the area in which the heat dissipation block 500 covers the second semiconductor chip 300 is not limited to the above numerical range. Meanwhile, the semiconductor device 400 may overlap the first semiconductor chip 200.

The semiconductor package 1000 of the present example embodiments may have an FO wafer level package (FOWLP) structure to improve heat dissipation characteristics, implement a small form factor, and improve reliability. In detail, the heat dissipation block 500 is disposed on the third redistribution substrate 100-3 in a structure that largely overlaps the second semiconductor chip 300, and the second semiconductor chip 300 in contact with the second redistribution substrate 100-2 is connected to the first redistribution substrate 100-1 through the first through-post 600-1, thereby improving the heat dissipation effect of the second semiconductor chip 300. Furthermore, the first semiconductor chip 200 is in contact with the first redistribution substrate 100-1 and connected to the second redistribution substrate 100-2 through the first connection terminal 220, thereby improving heat dissipation effect of the first semiconductor chip 200.

By arranging the first semiconductor chip 200 and the second semiconductor chip 300 to overlap in the Z-direction, the semiconductor package 1000 of the present example embodiments may implement a small form factor. For example, the semiconductor package 1000 of the present example embodiments may reduce the area by 30% or more compared to a package structure in which the first semiconductor chip 200 and the second semiconductor chip 300 are arranged side by side in the horizontal direction.

The semiconductor package 1000 of the present example embodiments is implemented to have improved signal integrity (SI) characteristics and reliability by shortening a connection path between the first semiconductor chip 200 and the second semiconductor chip 300. In detail, the first semiconductor chip 200 and the second semiconductor chip 300 are connected through a portion of the second redistribution substrate 100-2 corresponding to an overlap region OLA, thereby shortening the connection path and improving SI characteristics accordingly. For example, when the connection between the first semiconductor chip 200 and the second semiconductor chip 300 is implemented through the first redistribution substrate 100-1, the number of layers of the redistribution line 103 within the first redistribution substrate 100-1 may increase and the connection path may become longer resultantly, so SI characteristics may deteriorate. In addition, in order to reduce resistance of redistribution lines of many layers as much as possible, connection by stacked vias may be introduced, but in the case of stacked vias, reliability may be problematic due to damage, such as cracks. Meanwhile, the connection between the first semiconductor chip 200 and the second semiconductor chip 300 may be considered using a bridge-chip. However, the use of a bridge-chip is disadvantageous in terms of process and cost, and if the bridge-chip is disposed on a lower surface of the first redistribution substrate 100-1, a region without the external connection terminal 800 may increase, which may degrade the reliability of the entire semiconductor package.

FIGS. 2A to 2C are cross-sectional views illustrating the structure of the semiconductor device in the semiconductor package 1000 of FIG. 1 in more detail. The descriptions already given above with reference to FIG. 1 are briefly given or omitted.

Referring to FIG. 2A, the semiconductor device 400 may include one memory chip. The memory chip may include, for example, a volatile memory device, such as DRAM or SRAM, or a non-volatile memory device, such as flash memory. In the semiconductor package 1000 of the present example embodiments, the memory chip of the semiconductor device 400 may include, for example, a DRAM chip. The semiconductor device 400 having a flip-chip bonding structure using the third connection terminal 450 may be mounted on the third redistribution substrate 100-3. The third connection terminal 450 may include a metal pillar and solder or may include only solder.

Referring to FIG. 2B, a semiconductor device 400a may include a semiconductor package having a wire bonding structure. In detail, the semiconductor device 400a may include a package substrate 410 and a plurality of memory chips 420 stacked on the package substrate 410. The memory chip 420 have a wire bonding structure using an adhesive layer 425 and a wire 430 and may be mounted on the package substrate 410. The memory chip 420 of the semiconductor device 400a may include, for example, a volatile memory device, such as DRAM or SRAM, or a non-volatile memory device, such as flash memory. In the semiconductor package 1000 of the present example embodiments, the memory chip 420 of the semiconductor device 400a may include, for example, a DRAM chip. Meanwhile, the semiconductor device 400a may include an internal sealant that seals the memory chip 420 and the wire 430 on the package substrate 410. However, in FIG. 2B, the internal sealant is omitted for convenience.

In FIG. 2B, four memory chips 420 are stacked on the package substrate 410, but the number of memory chips 420 is not limited to four. For example, three or less memory chips 420 or five or more memory chips 420 may be stacked on the package substrate 410. In addition, the memory chip 420 is not limited to a staircase structure and may be stacked on the package substrate 410 in a zigzag structure or a combination of a staircase structure and a zigzag structure. The third connection terminal 450 may be disposed on the lower surface of the package substrate 410. Accordingly, the semiconductor device 400a of the package structure may also be mounted on the third redistribution substrate 100-3 through the third connection terminal 450.

Referring to FIG. 2C, a semiconductor device 400b may include a high bandwidth memory (HBM) package. In detail, the semiconductor device 400b may include a base chip 410a, a plurality of core chips 420a stacked on the base chip 410a, and an internal sealant 440. In addition, the base chip 410a and the core chips 420a may include a through-electrode 430a therein. However, the uppermost core chip 420a among the core chips 420a may not include the through-electrode 430a.

The base chip 410a may include logic devices. Accordingly, the base chip 410a may be a logic chip. The base chip 410a may be located below the core chips 420a, may integrate signals from the core chips 420a and transmit the integrated signal externally, and may also transmit signals and power from an external source to the core chips 420a. Accordingly, the base chip 410a may be referred to as a buffer chip or control chip. Meanwhile, each of the core chips 420a may be a memory chip. For example, each of the core chips 420a may be a DRAM chip. Meanwhile, the core chip 420a may be stacked on the base chip 410a or the lower core chip 420a through pad-to-pad bonding, HB, bonding using connection terminals, or bonding using ACF. In FIG. 2C, four core chips 420a are stacked on the base chip 410a but the number of core chips 420a is not limited to four. For example, three or less or five or more core chips 420a may be stacked on the base chip 410a.

The third connection terminal 450 may be disposed on a lower surface of the base chip 410a. Accordingly, the semiconductor device 400b of the HBM package may also be mounted on the third redistribution substrate 100-3 through the third connection terminal 450. The core chips 420a on the base chip 410a may be sealed by the internal sealant 440. However, an upper surface of the uppermost core chip 420a among the core chips 420a may not be covered with the internal sealant 440. However, in other example embodiments, the upper surface of the uppermost core chip 420a may be covered with the internal sealant 440.

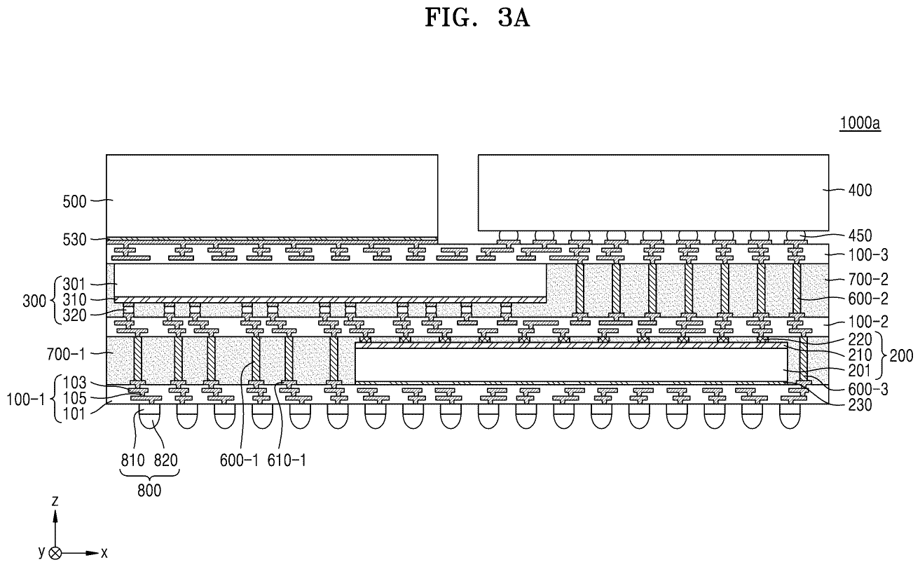

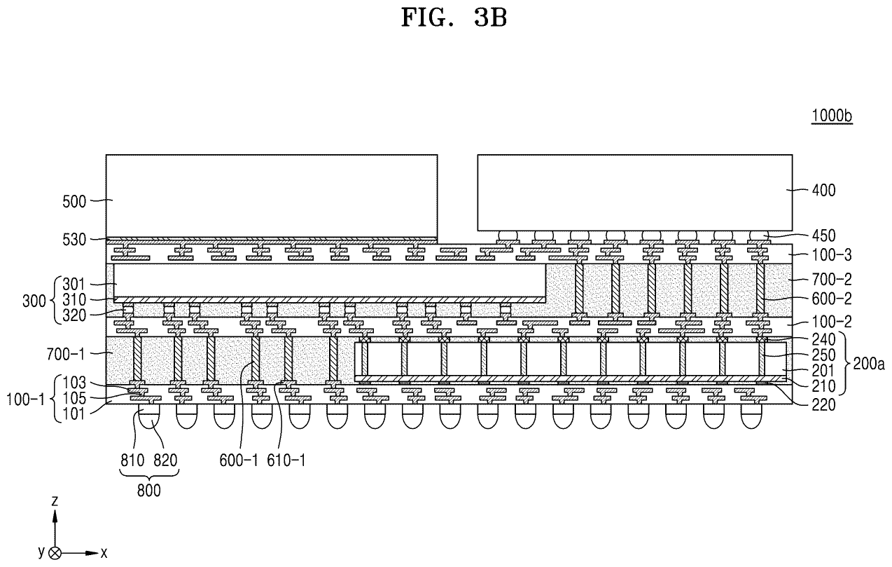

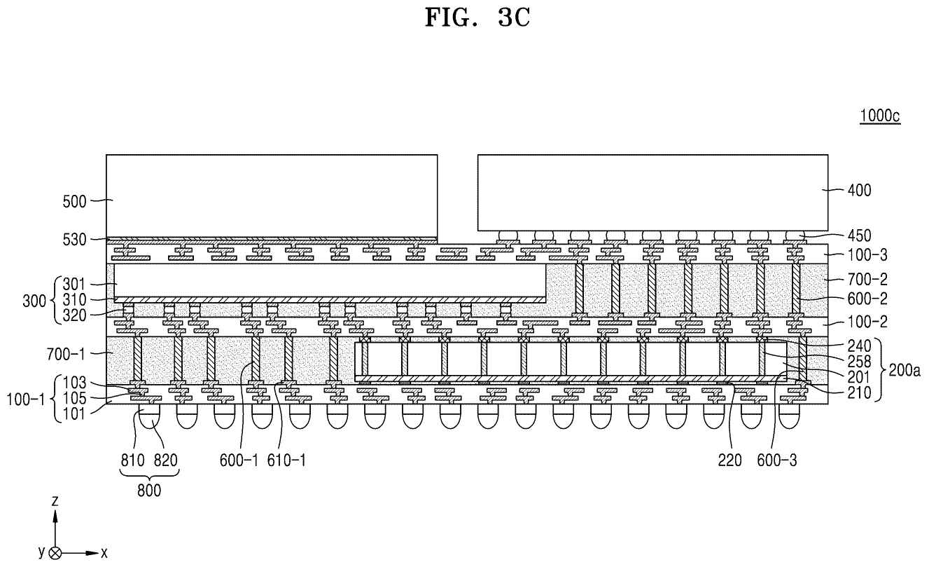

FIGS. 3A to 3C are cross-sectional views of semiconductor packages 1000a, 1000b, and 1000c according to some example embodiments. The descriptions already given above with reference to FIGS. 1 to 2C are briefly given or omitted.

Referring to FIG. 3A, the semiconductor package 1000a of the present example embodiments may be different from the semiconductor package 1000 of FIG. 1 in that a third through-post 600-3 is provided. In detail, the semiconductor package 1000a of the present example embodiments may include the first to third redistribution substrates 100-1 to 100-3, the first semiconductor chip 200, the second semiconductor chip 300, the semiconductor device 400, the heat dissipation block 500, the first to third through-posts 600-1 to 600-3, the first and second sealants 700-1 and 700-2, and the external connection terminal 800.

The first to third redistribution substrates 100-1 to 100-3, the first semiconductor chip 200, the second semiconductor chip 300, the semiconductor device 400, the heat dissipation block 500, the first and second through-posts 600-1 and 600-2, the first and second sealants 700-1 and 700-2, and the external connection terminal 800 are the same as those of the semiconductor package 1000 described above with reference to FIG. 1

The third through-post 600-3 may be disposed on the first redistribution substrate 100-1 to the right of the first semiconductor chip 200 in the X-direction. For example, the third through-posts 600-3 may be arranged in a row in a Y-direction on the first redistribution substrate 100-1 on the right side of the first semiconductor chip 200 in the X-direction. However, in some example embodiments, the third through-posts 600-3 may be arranged in a plurality of rows in the Y-direction. In addition, in some example embodiments, the third through-post 600-3 may be disposed on the first redistribution substrate 100-1 on both sides of the first semiconductor chip 200 in the Y-direction.

The third through-post 600-3 may be connected to the semiconductor device 400 through the second redistribution substrate 100-2, the second through-post 600-2, and the third redistribution substrate 100-3. In this manner, the third through-post 600-3 is disposed on the first redistribution substrate 100-1 in a lower portion of the semiconductor device 400, so that power may be effectively transferred to the semiconductor device 400 through the third through-post 600-3. For example, a power transmission path to the semiconductor device 400 may be configured to be shortest using the third through-post 600-3, the second redistribution substrate 100-2, the second through-post 600-2, and the third redistribution substrate 100-3. For example, a power transmission path to the semiconductor device 400 may be configured to be shorter using the third through-post 600-3, the second redistribution substrate 100-2, the second through-post 600-2, and the third redistribution substrate 100-3 than using the first through-post 600-1, the second redistribution substrate 100-2, the second through-post 600-2, and the third redistribution substrate 100-3.

Referring to FIG. 3B, the semiconductor package 1000b of the present example embodiments may be different from the semiconductor package 1000 of FIG. 1 in the structure and coupling structure of a first semiconductor chip 200a. In detail, the semiconductor package 1000b of the present example embodiments may include the first to third redistribution substrates 100-1 to 100-3, the first semiconductor chip 200a, the second semiconductor chip 300, the semiconductor device 400, the heat dissipation block 500, first and second through-posts 600-1 and 600-2, the first and second sealants 700-1 and 700-2, and the external connection terminal 800.

The first to third redistribution substrates 100-1 to 100-3, the second semiconductor chip 300, the semiconductor device 400, the heat dissipation block 500, the first and second through-posts 600-1 and 600-2, the first and second sealants 700-1 and 700-2, and the external connection terminal 800 are the same as those of the semiconductor package 1000 described above with reference to FIG. 1.

In the semiconductor package 1000b of the present example embodiments, the first semiconductor chip 200a may be different from the first semiconductor chip 200 of the semiconductor package 1000 of FIG. 1 in structure and the coupling structure between the first and second redistribution substrates 100-1 and 100-2 and may be substantially the same in terms of functionality. Accordingly, the first semiconductor chip 200a may be a logic chip and may include a plurality of logic devices therein. For example, the first semiconductor chip 200a may be an NPU chip or a modem chip.

The first semiconductor chip 200a may include the substrate 201, the active layer 210, the first connection terminal 220, a fourth connection terminal 240, and a through-electrode 250. The substrate 201, the active layer 210, and the first connection terminal 220 are the same as those of the first semiconductor chip 200 of the semiconductor package 1000 described above with reference to FIG. 1. However, in the semiconductor package 1000b of the present example embodiments, the active layer 210 of the first semiconductor chip 200a may be disposed below the substrate 201, and accordingly, a lower surface of the first semiconductor chip 200a may be the front side which is an active surface, and an upper surface of the first semiconductor chip 200a may be the back side which is an inactive surface. In other words, the lower surface of the active layer 210 may correspond to the front side of the first semiconductor chip 200a, and the upper surface of the substrate 201 may correspond to the back side of the first semiconductor chip 200a. A chip pad may be formed on the front side, which is the active surface, and the first connection terminal 220 may be disposed on the chip pad. Ultimately, the first connection terminal 220 may be disposed on the lower surface of the first semiconductor chip 200a, and therefore, the first semiconductor chip 200a may be mounted on the first redistribution substrate 100-1 through the first connection terminal 220.

Meanwhile, the arrangement position of the first semiconductor chip 200a on the first redistribution substrate 100-1 may be substantially the same as the arrangement position of the first semiconductor chip 200 of the semiconductor package 1000 of FIG. 1. For example, the first semiconductor chip 200a may be disposed to be biased to the right in the X-direction on the first redistribution substrate 100-1, as shown in FIG. 3B.

The through-electrode 250 may extend in the vertical direction, that is, the Z-direction, to pass through the substrate 201. The lower surface of the through-electrode 250 may be connected to an interconnection line of a multi-interconnection layer of the active layer 210, and the upper surface of the through-electrode 250 may be connected to the fourth connection terminal 240. For example, an upper pad may be disposed on the upper surface of the through-electrode 250, and the fourth connection terminal 240 may be connected to the through-electrode 250 through the upper pad. Accordingly, the first semiconductor chip 200a may be connected to the second redistribution substrate 100-2 through the through-electrode 250 and the fourth connection terminal 240. In addition, the first semiconductor chip 200a may be connected to the second semiconductor chip 300 through the through-electrode 250 and the second redistribution substrate 100-2. Furthermore, the first semiconductor chip 200a may be connected to the semiconductor device 400 through the through-electrode 250, the second redistribution substrate 100-2, the second through-post 600-2, and the third redistribution substrate 100-3. Meanwhile, in some embodiments, the fourth connection terminal 240 may be omitted, and the through-electrode 250 may be directly connected to the second redistribution substrate 100-2 through the upper pad on the through-electrode 250.

Because the through-electrode 250 has a structure that passes through silicon constituting the substrate 201, the through-electrode 250 may be referred to as a through silicon via (TSV). For reference, the through-electrode 250 may be divided into a via-first structure formed before the IC layer of the active layer 210 is formed, a via-middle structure formed before the formation of the multi-interconnection layer of the active layer 210 after the formation of the IC layer, and a via-last structure formed after the multi-interconnection layers is formed. In FIG. 3B, the through-electrode 250 may correspond to, for example, the via-middle structure. However, the inventive concepts are not limited thereto, and in the semiconductor package 1000b of the present example embodiments, the through-electrode 250 may have the via-first or via-last structure.

Referring to FIG. 3C, the semiconductor package 1000c of the present example embodiments may have a composite structure of the semiconductor package 1000a of FIG. 3A and the semiconductor package 1000b of FIG. 3B. In detail, compared to the semiconductor package 1000 of FIG. 1, the semiconductor package 1000c of the present example embodiments may further include the third through-post 600-3 and may be different in the structure of the first semiconductor chip 200a and the coupling structure between the first and second redistribution substrates 100-1 and 100-2. The third through-post 600-3 is the same as that of the semiconductor package 1000a described above with reference to FIG. 3A, and the structure of the first semiconductor chip 200a and the coupling structure to the first and second redistribution substrates 100-1 and 100-2 are the same as those of the semiconductor package 1000b described above with reference to FIG. 3B.

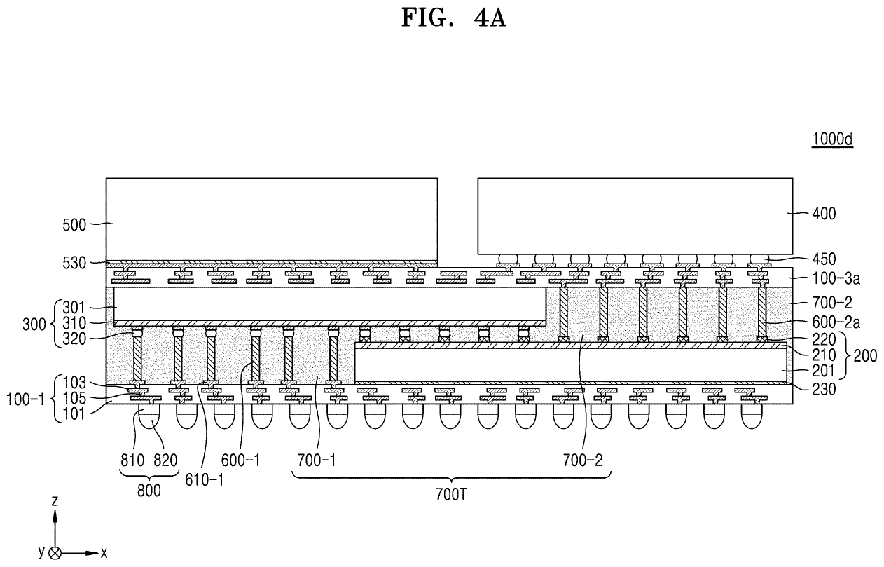

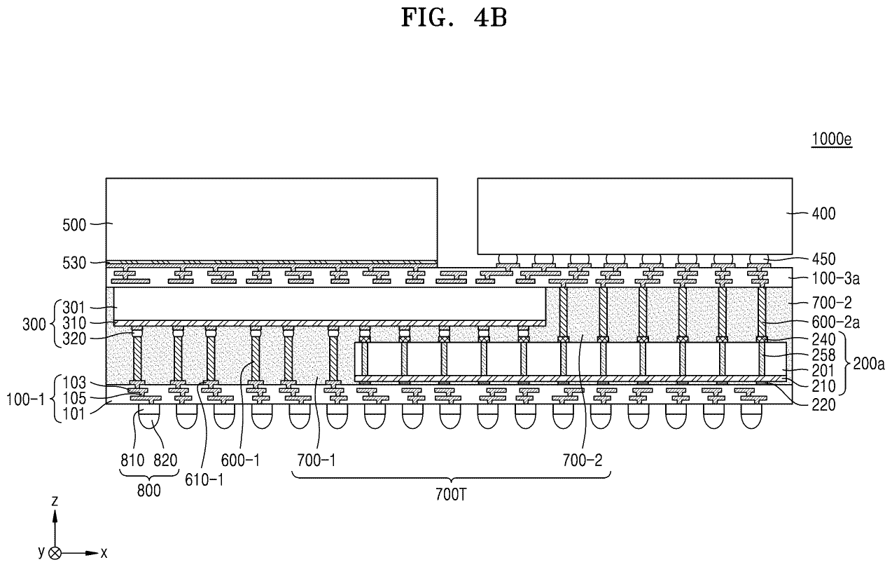

FIGS. 4A and 4B are cross-sectional views of semiconductor packages 1000d and 1000e according to some example embodiments. The descriptions already given above with reference to FIGS. 1 to 3C are briefly given or omitted.

Referring to FIG. 4A, the semiconductor package 1000d of the present example embodiments may be different from the semiconductor package 1000 of FIG. 1 in that the second redistribution substrate 100-2 is omitted, and accordingly, the coupling structure between the first and second semiconductor chips 200 and 300 is changed. In detail, the semiconductor package 1000d of the present example embodiments may include the first and third redistribution substrates 100-1 and 100-3a, the first semiconductor chip 200, the second semiconductor chip 300, the semiconductor device 400, the heat dissipation block 500, first and second through-posts 600-1 and 600-2a, the first and second sealants 700-1 and 700-2, and the external connection terminal 800. The first and third redistribution substrates 100-1 to 100-3a, the first semiconductor chip 200, the second semiconductor chip 300, the semiconductor device 400, the heat dissipation block 500, the first and second through-posts 600-1 and 600-2a, the first and second sealants 700-1 and 700-2, and the external connection terminal 800 are the same as those of the semiconductor package 1000 described above with reference to FIG. 1.

However, as the second redistribution substrate 100-2 is omitted, the coupling structures of the first and second semiconductor chips 200 and 300 and the first and second through-posts 600-1 and 600-2a may change. In detail, the second through-post 600-2a may be connected to the first connection terminal 220 of the first semiconductor chip 200. In addition, in the overlap region OLA in which the first semiconductor chip 200 overlaps the second semiconductor chip 300, the first connection terminal 220 of the first semiconductor chip 200 may be directly connected to the second connection terminal 320 of the second semiconductor chip 300. Furthermore, the first through-post 600-1 may be directly connected to the second connection terminal 320 of the second semiconductor chip 300. Meanwhile, the connection between the first semiconductor chip 200 and the second semiconductor chip 300 in the overlap region OLA may be made through pad-to-pad bonding, HB, or bonding using ACF.

Meanwhile, as the second through-post 600-2a is directly connected to the first semiconductor chip 200, the length of the second through-post 600-2a may increase by a thickness of the second redistribution substrate 100-2 from the second through-post 600-2 of the semiconductor package 1000 of FIG. 1. In addition, when the first sealant 700-1 and the second sealant 700-2 include the same material, the first sealant 700-1 and the second sealant 700-2 may be integrated to configure an entire sealant 700T. Accordingly, in the entire sealant 700T, the first sealant 700-1 may not be distinguished from the second sealant 700-2.

In the case of the semiconductor package 1000d of the present example embodiments, as the second redistribution substrate 1000-2 is omitted, the thickness of the entire semiconductor package may decrease by the thickness of the second redistribution substrate 1000-2. In addition, because the process of forming the second redistribution substrate 1000-2 is omitted, the number of operations in the semiconductor package manufacturing process may be reduced and materials may be saved. Accordingly, the manufacturing costs of the semiconductor package may be significantly reduced.

Referring to FIG. 4B, the semiconductor package 1000e of the present example embodiments may be different from the semiconductor package 1000d of FIG. 4A in the structure and coupling structure of the first semiconductor chip 200a. In detail, the semiconductor package 1000e of the present example embodiments may include the first and third redistribution substrates 100-1 and 100-3a, the first semiconductor chip 200a, the second semiconductor chip 300, the semiconductor device 400, the heat dissipation block 500, first and second through-posts 600-1 and 600-2a, the first and second sealants 700-1 and 700-2, and the external connection terminal 800.

The first and third redistribution substrates 100-1 and 100-3, the second semiconductor chip 300, the semiconductor device 400, the heat dissipation block 500, the first and second through-posts 600-1 and 600-2a, the first and second sealants 700-1 and 700-2, and the external connection terminal 800 are the same as those of the semiconductor package 1000 described above with reference to FIG. 1.

Meanwhile, the first semiconductor chip 200a is the same as that of the semiconductor package 1000b described above with reference to FIG. 3B. However, as the second redistribution substrate 100-2 is omitted, the coupling structures of the first and second semiconductor chips 200a and 300 and the first and second through-posts 600-1 and 600-2a may change. In detail, the second through-post 600-2a may be connected to the fourth connection terminal 240 of the first semiconductor chip 200a. In addition, in the overlap region OLA in which the first semiconductor chip 200a overlaps the second semiconductor chip 300, the fourth connection terminal 240 of the first semiconductor chip 200a may be directly connected to the second connection terminal 320 of the second semiconductor chip 300. Furthermore, the first through-post 600-1 may be directly connected to the second connection terminal 320 of the second semiconductor chip 300. Meanwhile, the connection between the first semiconductor chip 200a and the second semiconductor chip 300 in the overlap region OLA may be made through pad-to-pad bonding, HB, or bonding using ACF.

Meanwhile, as the second through-post 600-2a is directly connected to the first semiconductor chip 200a, the length of the second through-post 600-2a may increase by the thickness of the second redistribution substrate 100-2 from the second through-post 600-2 of the semiconductor package 1000 of FIG. 1. In addition, when the first sealant 700-1 and the second sealant 700-2 include the same material, the first sealant 700-1 and the second sealant 700-2 may be integrated to configure the entire sealant 700T. Accordingly, in the entire sealant 700T, the first sealant 700-1 may not be distinguished from the second sealant 700-2.

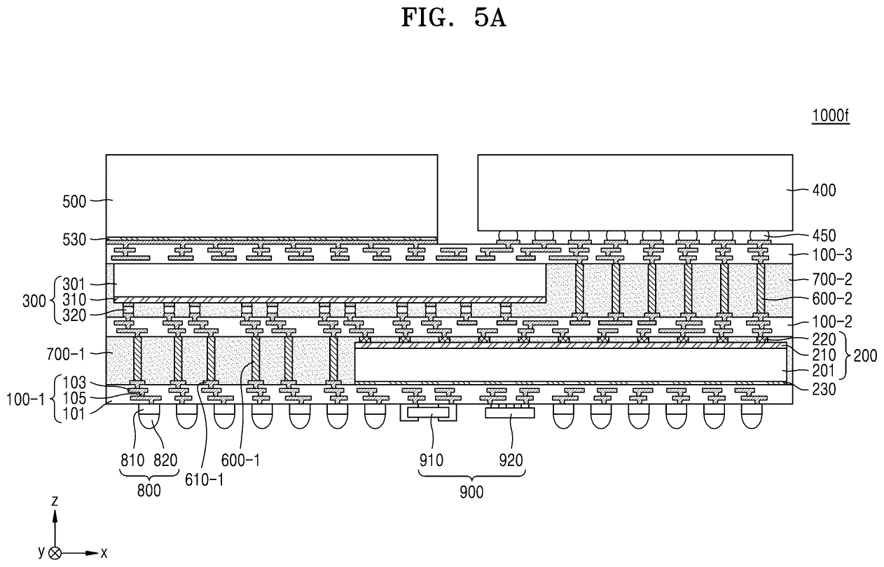

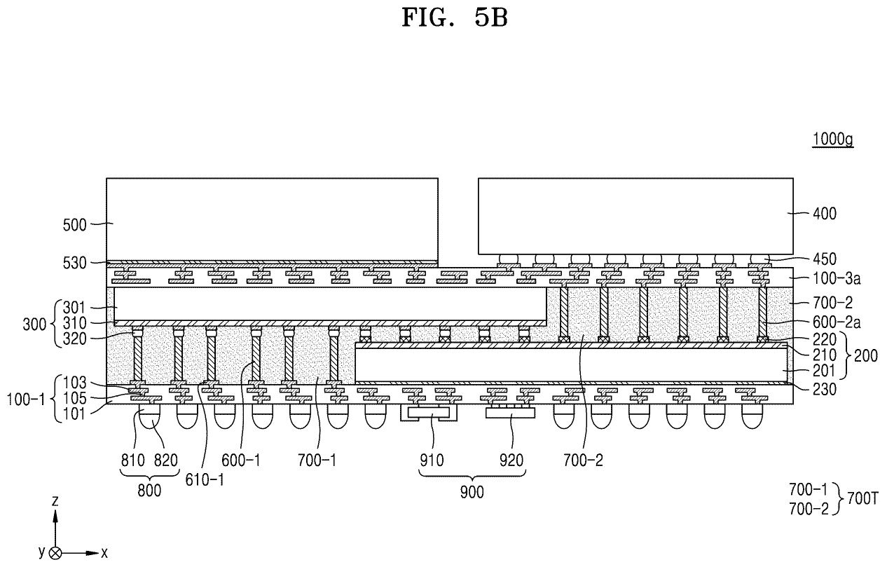

FIGS. 5A and 5B are cross-sectional views of semiconductor packages 1000f and 1000g according to some example embodiments. The descriptions already given above with reference to FIGS. 1 to 4B are briefly given or omitted.

Referring to FIG. 5A, the semiconductor package 1000f of the present example embodiments is similar to the semiconductor package 1000 of FIG. 1 but may include a passive device 900 disposed on the lower surface of the first redistribution substrate 100-1. In some embodiments, the passive device 900 may be disposed on the upper surface of or inside the first redistribution substrate 100-1. In addition, the passive device 900 may be disposed on the lower surface or upper surface of or inside the second redistribution substrate 100-2 or the third redistribution substrate 100-3. For example, in the case of the semiconductor packages 1000 and 1000a to 1000e of FIGS. 1 and 3A to 4B, the passive device may be disposed inside at least one of the first to third redistribution substrates 100-1 to 100-3. The passive device 900 may include a two-terminal device, such as a resistor, inductor, or capacitor. In the semiconductor package 1000f of the present example embodiments, the passive device 900 may include, for example, a multi-layer ceramic capacitor (MLCC) 910 and a Si-capacitor 920.

Referring to FIG. 5B, the semiconductor package 1000g of the present example embodiments is similar to the semiconductor package 1000d of FIG. 4A but may include the passive device 900 disposed on the lower surface of the first redistribution substrate 100-1. In some embodiments, the passive device 900 may be disposed on the upper surface of or inside the first redistribution substrate 100-1. In addition, the passive device 900 may be disposed on the lower or upper surface of or inside the second redistribution substrate 100-2 or the third redistribution substrate 100-3. In the semiconductor package 1000g of the present embodiment, the passive device 900 may include, for example, the MLCC 910 and the Si-capacitor 920.

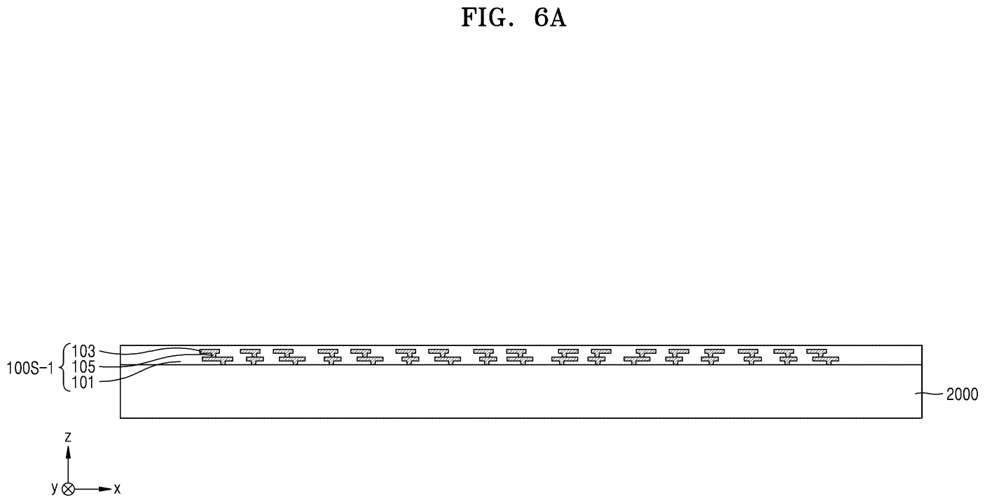

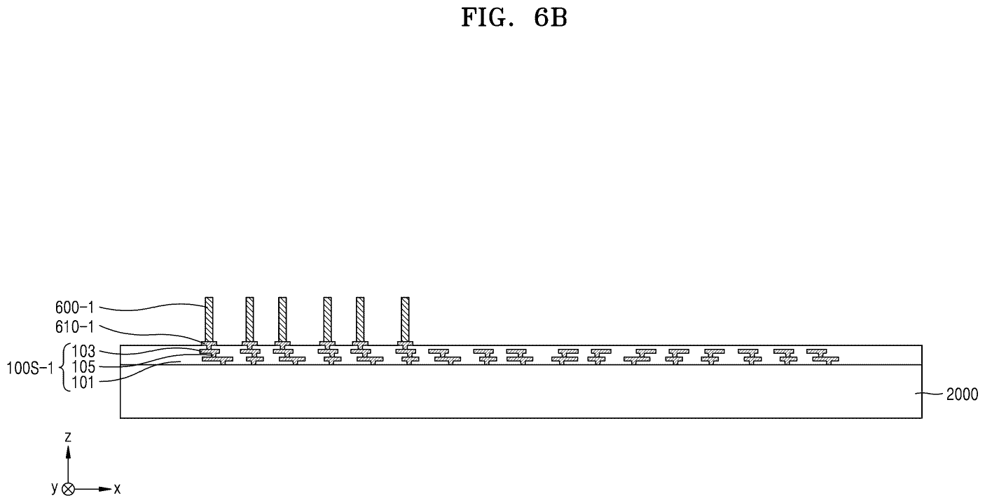

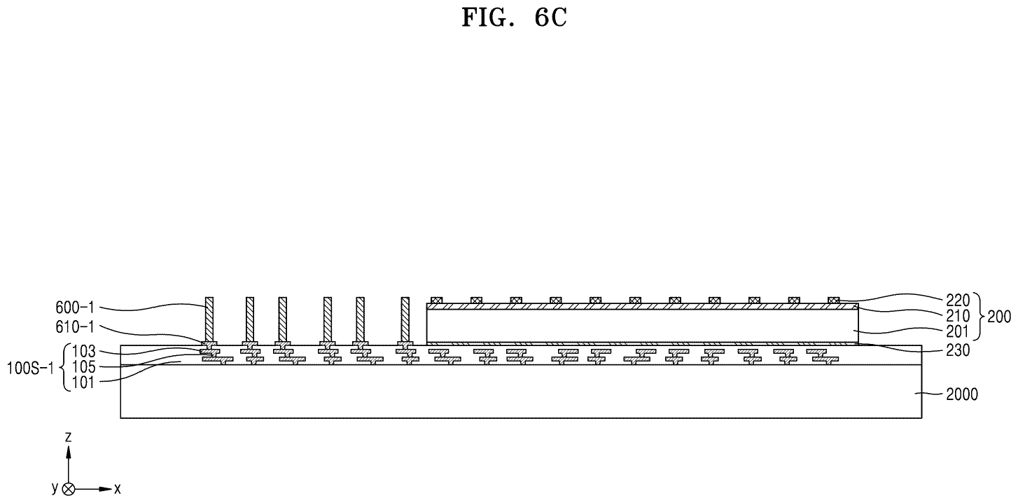

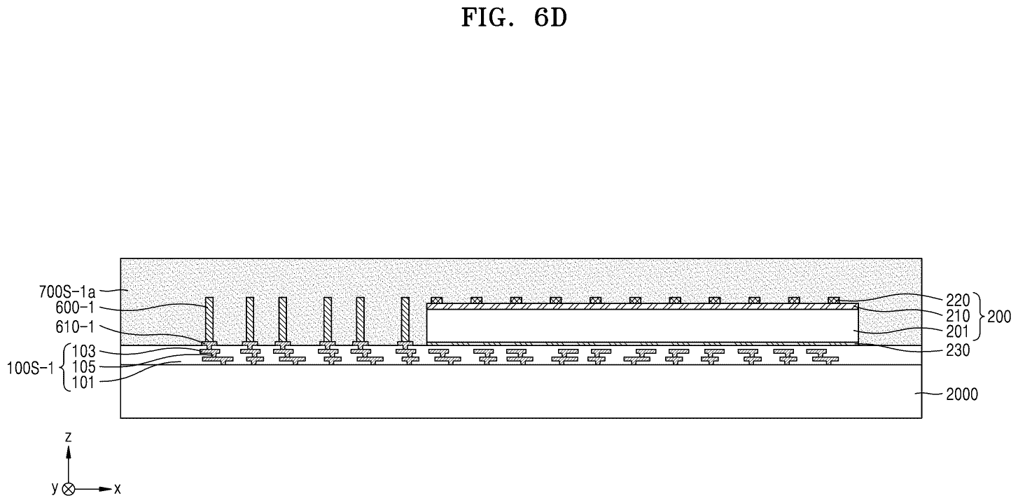

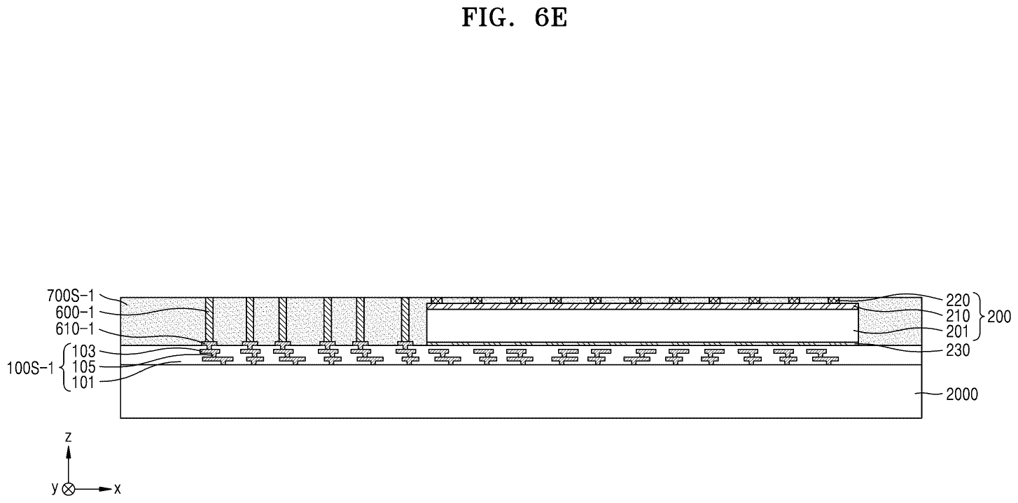

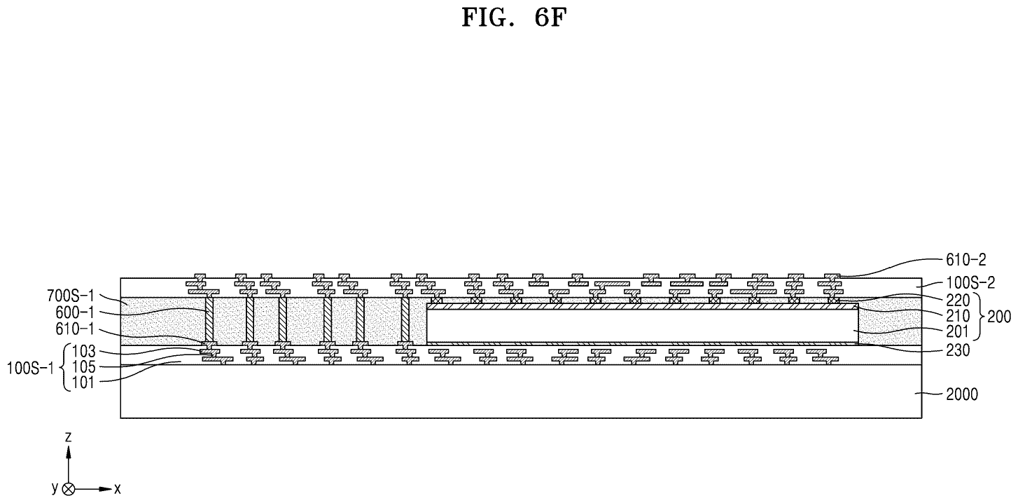

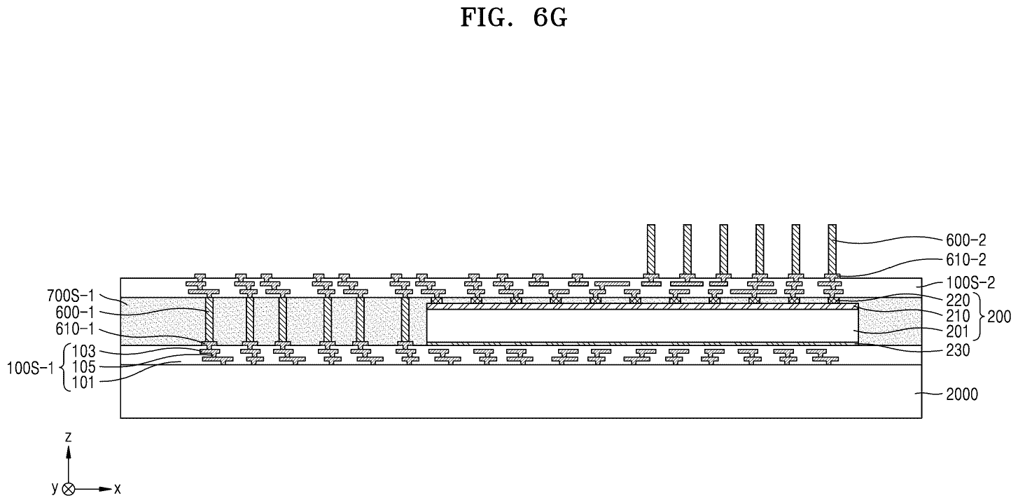

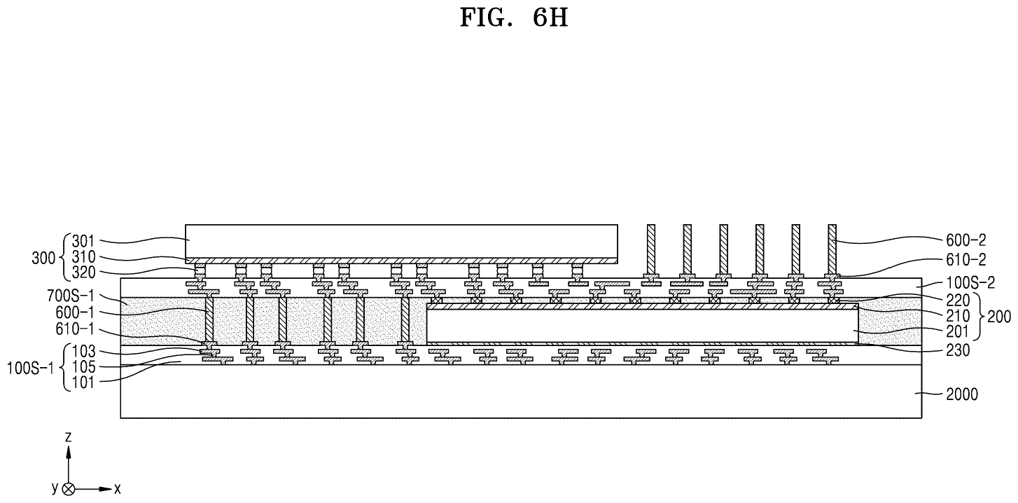

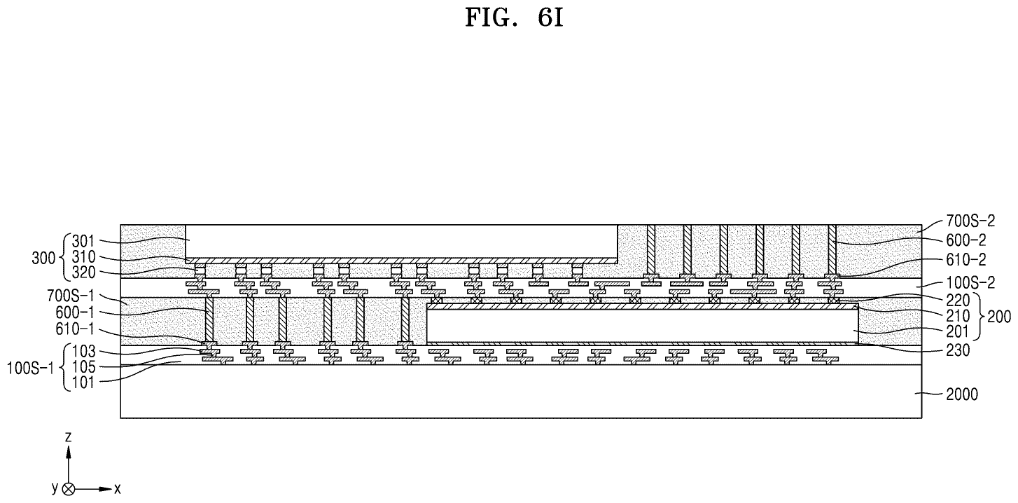

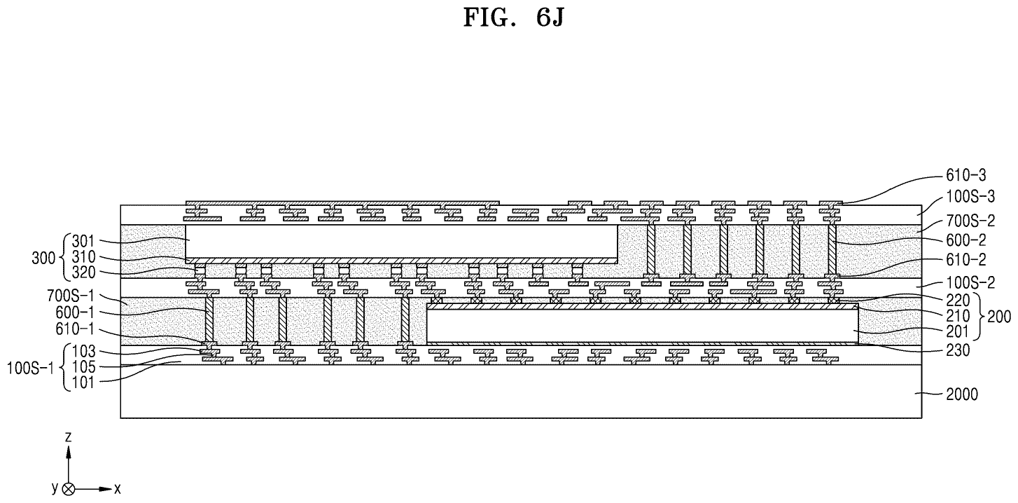

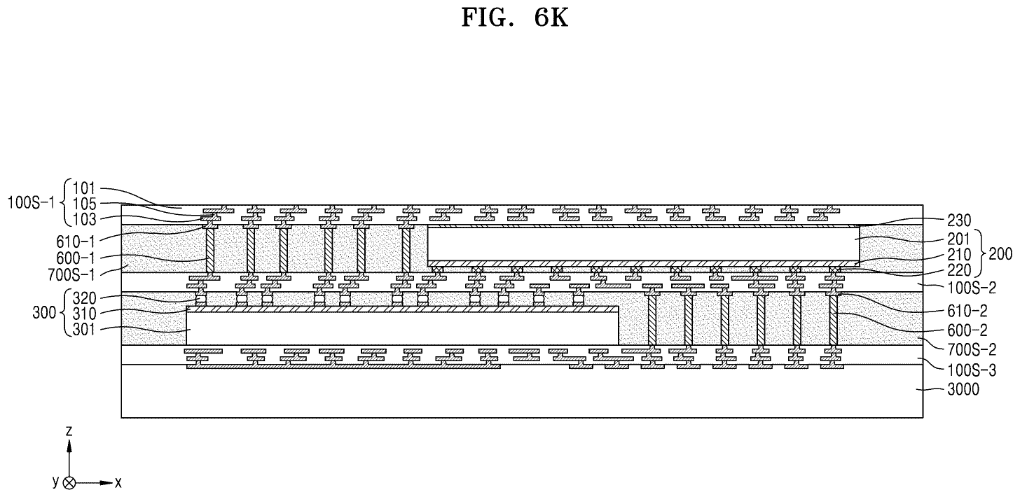

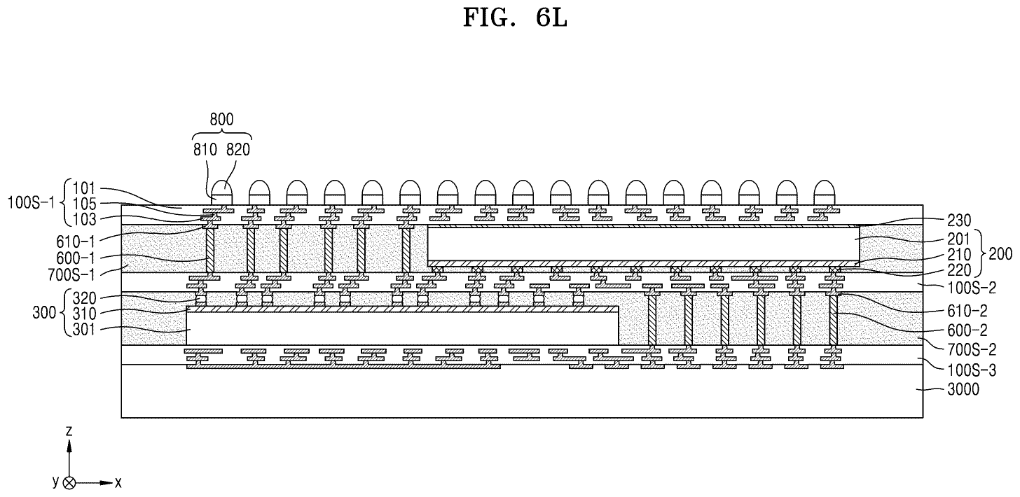

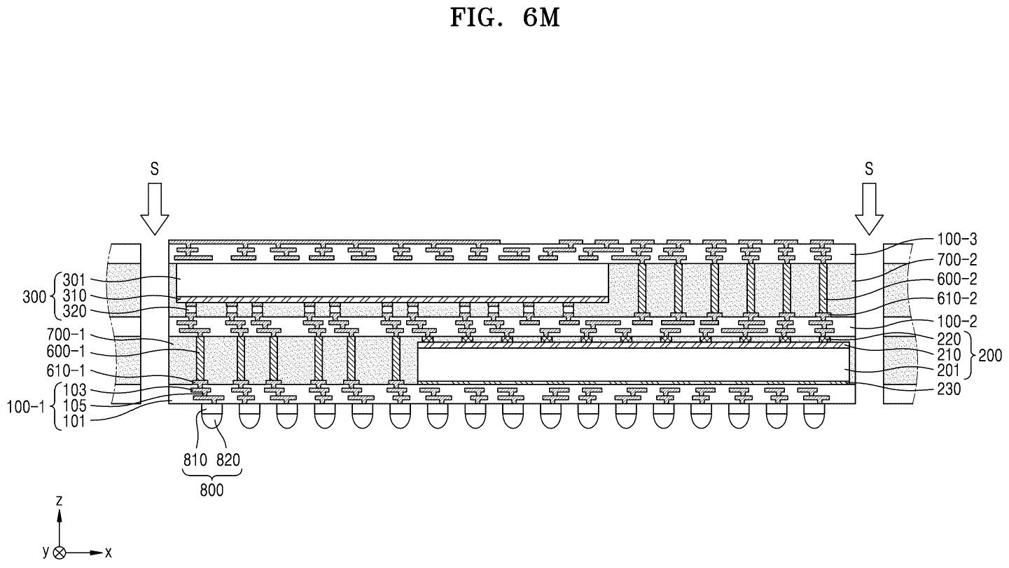

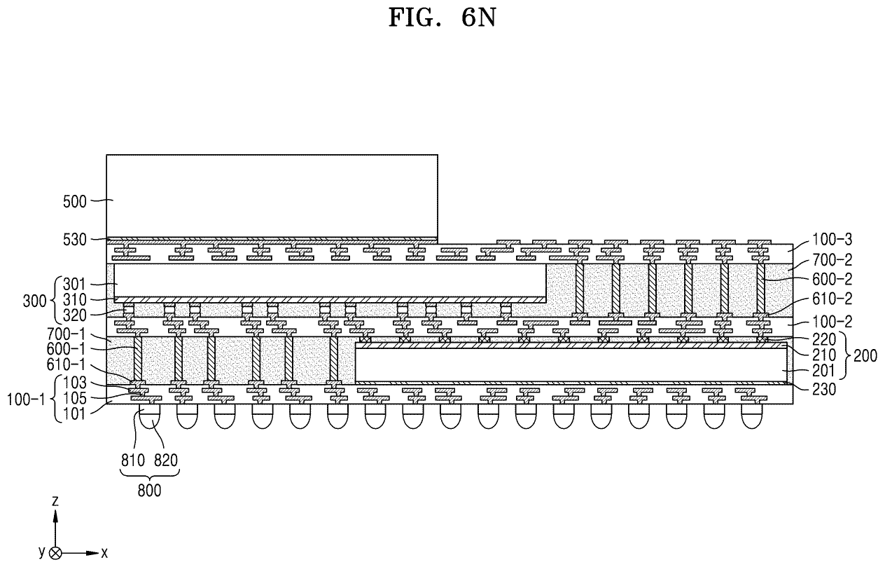

FIGS. 6A to 6N are cross-sectional views schematically illustrating the process of a method of manufacturing a semiconductor package according to some example embodiments. Descriptions are given with reference to FIG. 1 together, and the descriptions already given above with reference to FIGS. 1 to 5B are briefly given or omitted.

Referring to FIG. 6A, in the method of manufacturing a semiconductor package of the present example embodiments, first, a lower redistribution substrate 100S-1 is formed. The lower redistribution substrate 100S-1 may include a body insulating layer 101, a redistribution line 103, and a vertical via 105. The lower redistribution substrate 100S-1 may be formed on a first carrier substrate 2000. The first carrier substrate 2000 may be a large-sized substrate, such as a wafer. In addition, the lower redistribution substrate 100S-1 formed on the first carrier substrate 2000 may be a large-sized redistribution substrate including a plurality of first redistribution substrates 100-1. Although not shown, an adhesive layer may be located between the lower redistribution substrate 100S-1 and the first carrier substrate 2000. The adhesive layer may adhere and secure the lower redistribution substrate 100S-1 to the first carrier substrate 2000.

For reference, as is described below, various components may be formed on a large-sized redistribution substrate and individualized through a sawing process or singulation process to manufacture a semiconductor package, and such a semiconductor package manufactured in this manner is referred to as a wafer level package (WLP). Hereinafter, for convenience of description, only components corresponding to one first redistribution substrate 100-1 are shown in FIG. 6A and the drawings that follow.

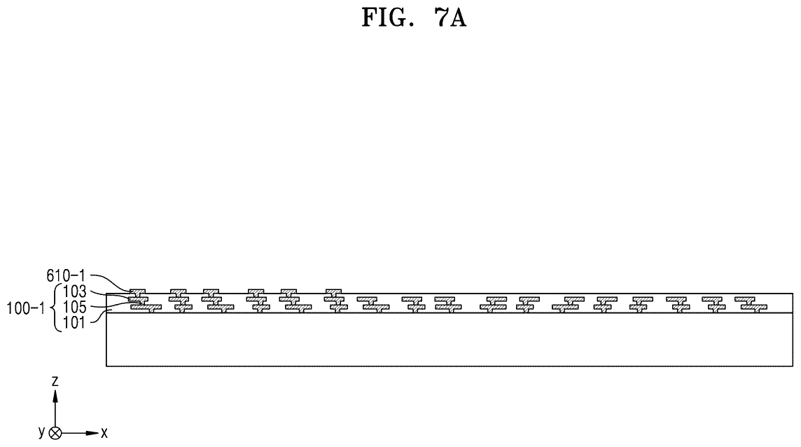

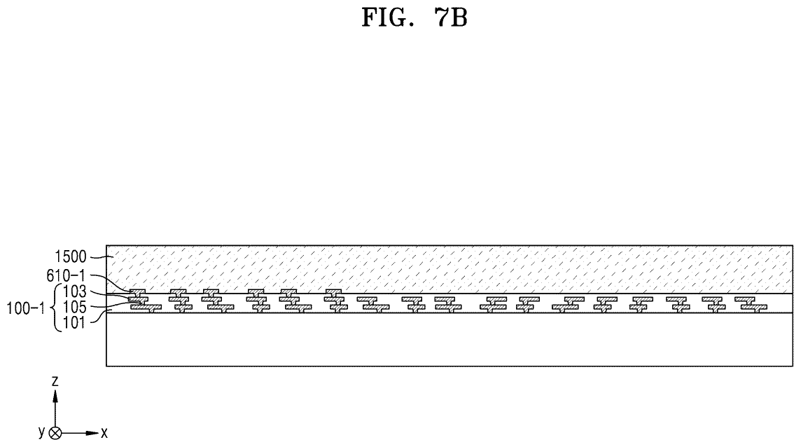

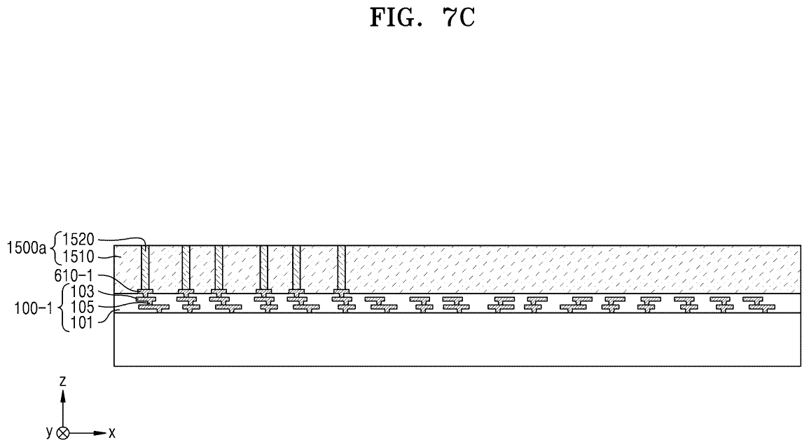

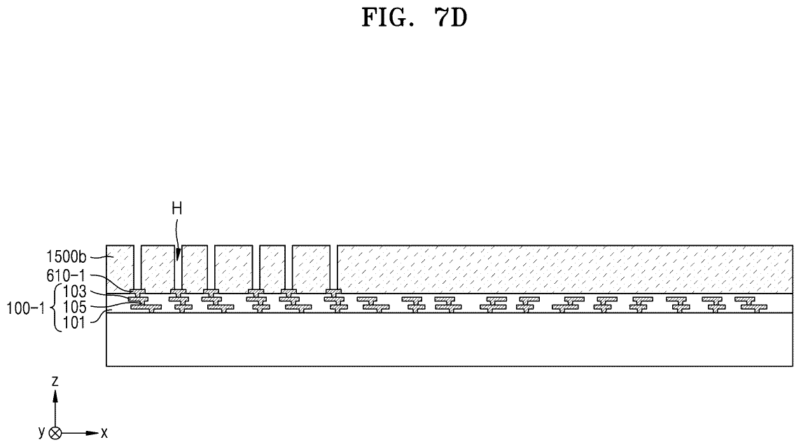

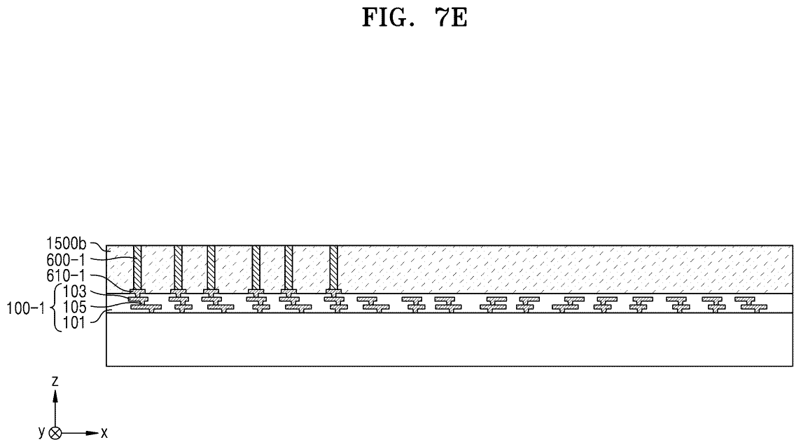

Referring to FIG. 6B, thereafter, the first through-post 600-1 is formed on the lower redistribution substrate 100S-1. The first through-post 600-1 may be formed on the left portion of the lower redistribution substrate 100S-1 in the X-direction by considering a portion in which the first semiconductor chip 200 is to be located later. The method of forming the first through-post 600-1 is described below in detail with reference to FIGS. 7A to 7E.

In addition, in the case of manufacturing the semiconductor package 1000a of FIG. 3A, the third through-post 600-3 may be formed together with the first through-post 600-1. The third through-post 600-3 may be disposed on the right of the portion in which the first semiconductor chip 200 is to be located in the X-direction.

Referring to FIG. 6C, after forming the first through-post 600-1, the first semiconductor chip 200 is mounted in a portion in which the first through-post 600-1 is not located on the lower redistribution substrate 100S-1, that is, on the right side in the X-direction on the lower redistribution substrate 100S-1. In detail, the first semiconductor chip 200 may be mounted on the lower redistribution substrate 100S-1 through the adhesive layer 230. Meanwhile, the first connection terminal 220 may be disposed on the upper surface of the first semiconductor chip 200. The first semiconductor chip 200 may be the same as that described above with regard to the semiconductor package 1000 described above with reference to FIG. 1.

In addition, in the case of manufacturing the semiconductor package 1000b of FIG. 3B, the first semiconductor chip 200a including the through-electrode 250 may be mounted on the lower redistribution substrate 100S-1. In addition, the first semiconductor chip 200a may be mounted on the lower redistribution substrate 100S-1 through the first connection terminal 220, and the fourth connection terminal 240 connected to the through-electrode 250 may be disposed on the upper surface of the first semiconductor chip 200a.

Referring to FIG. 6D, after mounting the first semiconductor chip 200, the first semiconductor chip 200 and the first through-post 600-1 are sealed with a lower sealant 700S-1a. The lower sealant 700S-1a may cover the side and upper surfaces of the first semiconductor chip 200 and the first through-post 600-1. In addition, the lower sealant 700S-1a may fill the space between the first connection terminals 220. The material of the lower sealant 700S-a is the same as that of the first sealant 700-1 of the semiconductor package 1000 described above with reference to FIG. 1.

Thereafter, referring to FIG. 6E, an upper portion of the lower sealant 700S-1a is removed through a mold grinding (MG) process. After the MG process, upper surfaces of the first connection terminal 220 of the first semiconductor chip 200 and the first through-post 600-1 may be exposed from the lower sealant 700S-1. In addition, as the upper surfaces of the first connection terminal 220 and the first through-post 600-1 are exposed through the MG process, the upper surfaces of the first connection terminal 220, the first through-post 600-1, and the lower sealant 700S-1 may be substantially coplanar with each other.

Referring to FIG. 6F, an intermediate redistribution substrate 100S-2 is formed above the first semiconductor chip 200, the first through-post 600-1, and the lower sealant 700S-1. The intermediate redistribution substrate 100S-2 may include a body insulating layer, a redistribution line, and a vertical via. The redistribution line of the intermediate redistribution substrate 100S-2 may be connected to the first through-post 600-1 and may also be connected to the first connection terminal 220 of the first semiconductor chip 200. Meanwhile, the intermediate redistribution substrate 100S-2 is a large-sized redistribution substrate and may include a plurality of second redistribution substrates 100-2.

Referring to FIG. 6G, after forming the intermediate redistribution substrate 100S-2, the second through-post 600-2 is formed on the intermediate redistribution substrate 100S-2.

The second through-post 600-2 may be formed in a right portion on the intermediate redistribution substrate 100S-2 in the X-direction, by considering the portion in which the second semiconductor chip 300 is to be located later. The method of forming the second through-post 600-2 may be substantially the same as the method of forming the first through-post 600-1.

Referring to FIG. 6H, after forming the second through-post 600-2, the second semiconductor chip 300 is mounted on the intermediate redistribution substrate 100S-2. In detail, the second semiconductor chip 300 may be mounted on the intermediate redistribution substrate 100S-2 through the second connection terminal 320 and may be disposed in a portion corresponding to the first through-post 600-1. For example, the second semiconductor chip 300 may be disposed on the left of the second through-post 600-2 in the X-direction.

The second connection terminal 320 may include a metal pillar 322 and solder 324. In some embodiments, the second connection terminal 320 may include only solder 324. When mounting the second semiconductor chip 300 using the second connection terminal 320, various bonding processes, such as reflow, thermal compression bonding (TCB), laser assisted bonding (LAB), and/or the like may be used. The second semiconductor chip 300 may be the same as that described above with regard to the semiconductor package 1000 described above with reference to FIG. 1.

Referring to FIG. 6I, after the second semiconductor chip 300 is mounted, the second semiconductor chip 300 and the second through-post 600-2 are sealed with an upper sealant 700S-2. The upper sealant 700S-2 may cover the side surfaces of the second through-post 600-2 and the side and lower surfaces of the second semiconductor chip 300. In addition, the upper sealant 700S-2 may fill the space between the second connection terminals 320. The material of the upper sealant 700S-2 may be substantially the same as that of the lower sealant 700S-1. In addition, the formation process of the upper sealant 700S-2 may be substantially the same as the formation process of the lower sealant 700S-1. For example, first, an initial upper sealant is formed to cover the side and upper surfaces of the second semiconductor chip 300 and the second through-post 600-2. Thereafter, an upper portion of the initial upper sealant is removed through an MG process to expose the upper surfaces of the second semiconductor chip 300 and the second through-post 600-2. Accordingly, the upper surfaces of the second semiconductor chip 300 and the second through-post 600-2 may be exposed from the upper sealant 700S-2. In addition, the upper surfaces of the second semiconductor chip 300, the second through-post 600-2, and the upper sealant 700S-2 may be coplanar with each other.

Referring to FIG. 6J, after the upper sealant 700S-2 is formed, the upper redistribution substrate 100S-3 is formed above the second semiconductor chip 300, the second through-post 600-2, and the upper sealant 700S-2. The upper redistribution substrate 100S-3 may include a body insulating layer, a redistribution line, and a vertical via. The redistribution line of the upper redistribution substrate 100S-3 may be connected to the second through-post 600-2. Meanwhile, the upper redistribution substrate 100S-3 is a large-sized redistribution substrate and may include a plurality of third redistribution substrates 100-3.

Referring to FIG. 6K, after the upper redistribution substrate 100S-3 is formed, the lower redistribution substrate 100S-1 and the structures thereon are separated from the first carrier substrate 2000, turned upside down, and attached to a second carrier substrate 3000. In other words, as shown in FIG. 6K, the upper redistribution substrate 100S-3 is attached to the second carrier substrate 3000, and the second semiconductor chip 300, the intermediate redistribution substrate 100S-2, the first semiconductor chip 200, and the lower redistribution substrate 100S-1 may be sequentially arranged on the upper redistribution substrate 100S-3. Although not shown, an adhesive layer may be located between the upper redistribution substrate 100S-3 and the second carrier substrate 3000.

Thereafter, referring to FIG. 6L, the external connection terminal 800 is attached to the upper surface of the lower redistribution substrate 100S-1. The upper surface of the lower redistribution substrate 100S-1 in FIG. 6L may correspond to the lower surface of the first redistribution substrate 100-1 in the semiconductor package 1000 of FIG. 1. Meanwhile, the external connection terminal 800 is the same as that of the semiconductor package 1000 described above with reference to FIG. 1. In addition, in the case of manufacturing the semiconductor package 1000f of FIG. 5A, the passive device 900 may be attached to the upper surface of the lower redistribution substrate 100S-1.

Referring to FIG. 6M, after the external connection terminal 800 is attached, the entire structure may be separated from the second carrier substrate 3000, and a sawing process S may be performed on the entire structure. For example, the sawing process S may be performed in a ring mount device. Through the sawing process S, a plurality of structures included in the entire structure may be individualized.

Referring to FIG. 6N, the heat dissipation block 500 may then be disposed on the third redistribution substrate 100-3. In detail, the heat dissipation block 500 may be disposed on the third redistribution substrate 100-3 through the adhesive layer 550 and may be disposed in a portion corresponding to the second semiconductor chip 300. For example, the heat dissipation block 500 may be disposed on the left on the third redistribution substrate 100-3 in the X-direction.

Subsequently, the semiconductor device 400 may be mounted on the third redistribution substrate 100-3. In detail, the semiconductor device 400 may be disposed on the third redistribution substrate 100-3 through the third connection terminal 450 and may be disposed in a portion corresponding to the second through-post 600-2. For example, the semiconductor device 400 may be disposed on the right side of the heat dissipation block 500 in the X-direction. Meanwhile, according to some example embodiments, the order in which the heat dissipation block 500 and the semiconductor device 400 are mounted may change. By mounting the heat dissipation block 500 and the semiconductor device 400 on the third redistribution substrate 100-3, the semiconductor package 1000 of FIG. 1 may be completed.

FIGS. 7A to 7E are cross-sectional views illustrating the operation of FIG. 6C in more detail.

Referring to FIG. 7A, in the method of manufacturing a semiconductor package of the present example embodiments, the first through-post 600-1 may be formed on the lower redistribution substrate 100S-1 through the following process. First, the lower pad 610-1 is formed on the lower redistribution substrate 100S-1. The lower pad 610-1 may include various metal materials, such as Cu, Ti, Ta, TiN, TaN, etc. In the method of manufacturing a semiconductor package of the present example embodiments, for example, the lower pad 610-1 may include Cu.

Referring to FIG. 7B, photo-resist (PR) 1500 is subsequently applied on the lower redistribution substrate 100S-1. The PR 1500 may be applied, for example, through a spin coating method using a spin coater. The PR 1500 may be formed to have a thickness corresponding to the length of the first through-post 600-1.

Referring to FIG. 7C, after applying the PR 1500, an exposure process is performed. The exposure process may be performed using a mask including a certain pattern. For example, light may be allowed to transmit through a transparent portion of a transmissive mask to irradiate a certain portion of the PR 1500 with light. The chemical properties of the portion of PR 1500 irradiated with light may be changed. For example, after the exposure process, the PR 1500a may be divided into an unexposed portion 1510 and an exposed portion 1520. As can be seen through FIG. 7C, the exposed portion 1520 may be located in the left portion of the lower redistribution substrate 100S-1 in the X-direction.

Referring to FIG. 7D, after the exposure process, a development process is performed on the PR 1500a. In the development process, for example, the exposed portion 1520 may be removed. For example, the PR 1500a may be a positive PR. Meanwhile, according to some example embodiments, negative PR may be used. When negative PR is used, unexposed portions may be removed during the development process.

As the exposed portion 1520 is removed through the development process, a PR pattern 1500b may be formed. The PR pattern 1500b may include a plurality of through-holes H. The lower pad 610-1 may be exposed to a bottom surface of the through-holes H. Meanwhile, after the development process, by-products, such as PR scum, etc. may remain inside the through-holes H. Accordingly, the by-products are removed through a cleaning process.

Referring to FIG. 7E, after the cleaning process, the first through-posts 600-1 are formed inside the through-holes H through electroplating. The first through-post 600-1 may include, for example, Cu. Although not shown, the first through-post 600-1 may also be formed in a portion of the upper surface of the PR pattern 1500b adjacent to the through-hole H outside the through-hole H.

After the first through-post 600-1 is formed, the PR pattern 1500b is removed. The PR pattern 1500b may be removed through an ashing/strip process. By removing the PR pattern 1500b, the first through-post 600-1 of FIG. 6C may be formed.

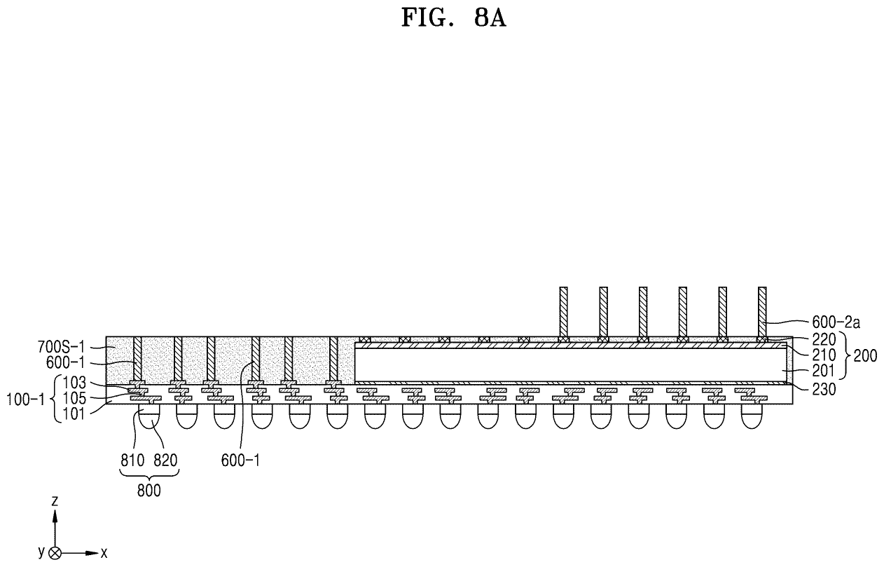

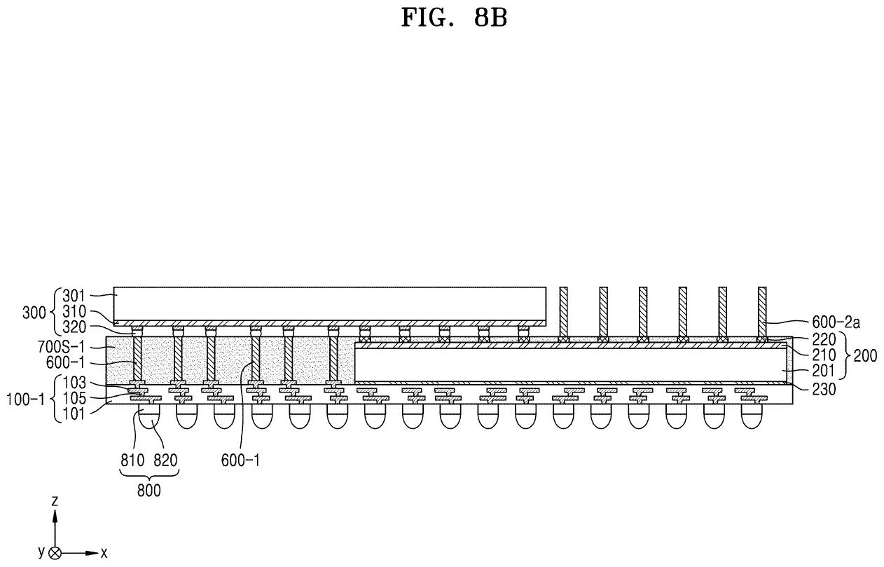

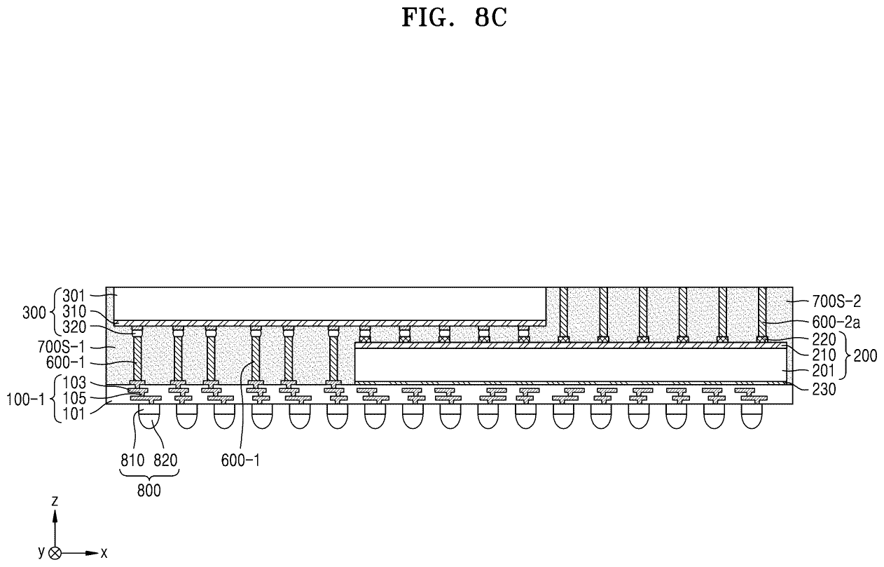

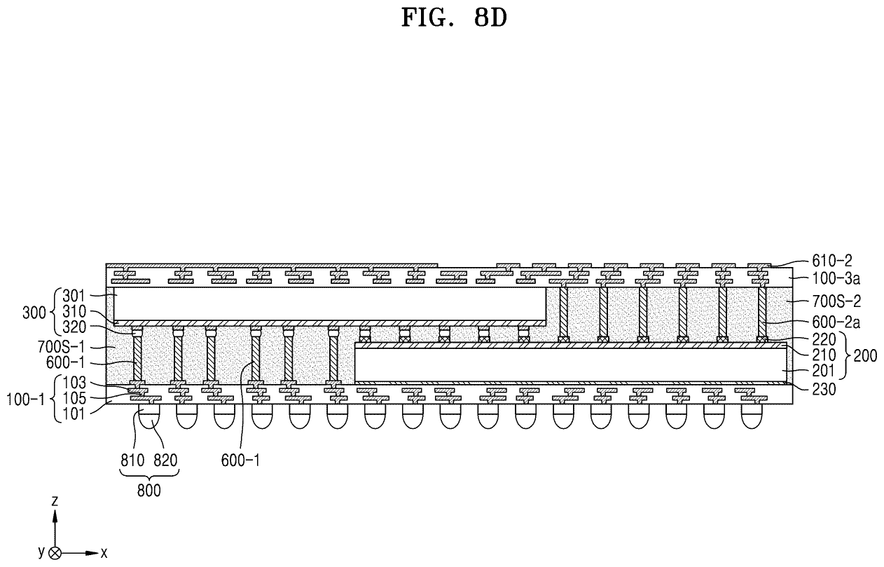

FIGS. 8A to 8D are cross-sectional views schematically illustrating a process of a method of manufacturing a semiconductor package according to some example embodiments. Descriptions are given with reference to FIG. 4A together, and the descriptions already given above with reference to FIGS. 6A to 7E are briefly given or omitted.

Referring to FIG. 8A, the method of manufacturing a semiconductor package of the present example embodiments sequentially performs the processes of FIGS. 6A to 6E. Thereafter, the second through-post 600-2a is formed on the first semiconductor chip 200. The second through-post 600-2a may be formed to be connected to the first connection terminal 220 of the first semiconductor chip 200. The second through-post 600-2a may be formed using substantially the same method as the method of forming the first through-post 600-1. However, the first connection terminal 220 may be used as a seed metal instead of the upper pad 610-1, and the second through-post 600-2a may be formed on only some of the first connection terminals 220.

Referring to FIG. 8B, after the second through-post 600-2a is formed, the second semiconductor chip 300 is mounted on the first through-post 600-1 and the first semiconductor chip 200. In detail, the second semiconductor chip 300 may be mounted in a portion in which the first through-posts 600-1 are disposed and in a portion in which some of the first connection terminals 220 of the second semiconductor chip 300 are disposed through the second connection terminal 320. For example, the second connection terminal 320 may be coupled to all of the first through-posts 600-1 and may be coupled to some of the first connection terminals 220 of the second semiconductor chip 300. Accordingly, the second semiconductor chip 300 may at least partially overlap the first semiconductor chip 200 in the Z-direction.

Referring to FIG. 8C, after the second semiconductor chip 300 is mounted, the second semiconductor chip 300 and the second through-post 600-2a are sealed with the upper sealant 700S-2. The upper sealant 700S-2 may cover the side surfaces of the second through-post 600-2a and the side and lower surfaces of the second semiconductor chip 300. In addition, the upper sealant 700S-2 may fill the space between the second connection terminals 320. The material of the upper sealant 700S-2 may be substantially the same as that of the lower sealant 700S-1. In addition, the formation process of the upper sealant 700S-2 may be substantially the same as the formation process of the lower sealant 700S-1. For example, first, an initial upper sealant is formed to cover the side and upper surfaces of the second semiconductor chip 300 and the second through-post 600-2a. Thereafter, an upper portion of the initial upper sealant is removed through an MG process to expose the upper surfaces of the second semiconductor chip 300 and the second through-post 600-2a. Accordingly, the upper surfaces of the second semiconductor chip 300 and the second through-post 600-2a may be exposed from the upper sealant 700S-2. Meanwhile, the first sealant 700-1 and the second sealant 700-2 include the same material and the intermediate redistribution substrate 100S does not exist between the first sealant 700-1 and the second sealant 700-2, so that the first sealant 700-1 and the second sealant 700-2 may be integrated to form the entire sealant 700T.

Referring to FIG. 8D, after the upper sealant 700S-2 is formed, the upper redistribution substrate 100S-3 is formed above the second semiconductor chip 300, the second through-post 600-2a, and the upper sealant 700S-2. The upper redistribution substrate 100S-3 may include a body insulating layer, a redistribution line, and a vertical via. The redistribution line of the upper redistribution substrate 100S-3 may be connected to the second through-post 600-2a. Subsequently, the semiconductor package 1000d of FIG. 4A may be completed by performing the processes of FIGS. 6K to 6N.

While the inventive concepts have been particularly shown and described with reference to example embodiments thereof, it will be understood that various changes in form and details may be made therein without departing from the spirit and scope of the following claims.

1. A semiconductor package comprising:
a first redistribution substrate having a first side and a second side spaced apart in a first horizontal direction;
a first semiconductor chip on the first side of the first redistribution substrate;
a first through-post on the second side of the of the first redistribution substrate;
a second redistribution substrate on the first semiconductor chip and the first through-post, the second redistribution substrate having a first side and a second side spaced apart in the first horizontal direction;
a second semiconductor chip on the second side of the second redistribution substrate;
a second through-post on the first side of the second redistribution substrate;
a third redistribution substrate on the second semiconductor chip and the second through-post, the third redistribution substrate having a first side and a second side spaced apart in the first horizontal direction, the first side of the first redistribution substrate, the first side of the second redistribution substrate, and the first side of the third redistribution substrate being aligned in a vertical direction perpendicular to an upper surface of the first redistribution substrate;
a heat dissipation block on the second side of the third redistribution substrate; and
a semiconductor device on the first side of the third redistribution substrate.

2. The semiconductor package of claim 1, wherein the first semiconductor chip at least partially overlaps the second semiconductor chip in the vertical direction perpendicular to the upper surface of the first redistribution substrate.

3. The semiconductor package of claim 1, wherein the heat dissipation block overlaps the second semiconductor chip in the vertical direction perpendicular to the upper surface of the first redistribution substrate.

4. The semiconductor package of claim 1, further comprising:
a plurality of first through-posts; and
a plurality of second through-posts, wherein
a number of the first through-post in the plurality of first through-posts is greater than a number of the second through-posts in the plurality of second through-posts.

5. The semiconductor package of claim 1, wherein
the upper surface of the first semiconductor chip is an active surface and is coupled to a lower surface of the second redistribution substrate,
a lower surface of the second semiconductor chip is an active surface and is coupled to the upper surface of the second redistribution substrate, and
an active layer of the first semiconductor chip is connected to an active layer of the second semiconductor chip through the second redistribution substrate.

6. The semiconductor package of claim 1, wherein
the first semiconductor chip includes a through-electrode,
a lower surface of the first semiconductor chip is an active surface and the upper surface of the first semiconductor chip is coupled to a lower surface of the second redistribution substrate,
a lower surface of the second semiconductor chip is an active surface and is coupled to the upper surface of the second redistribution substrate, and
an active layer of the first semiconductor chip is connected to an active layer of the second semiconductor chip through the through-electrode and the second redistribution substrate.

7. The semiconductor package of claim 1, further comprising:
a third through-post on the first side of the first semiconductor chip in the first horizontal direction on the first redistribution substrate.

8. The semiconductor package of claim 1, further comprising:
a first sealant located between the first redistribution substrate and the second redistribution substrate and covering a side surface of the first through-post and a side surface and the upper surface of the first semiconductor chip; and
a second sealant located between the second redistribution substrate and the third redistribution substrate and covering a side surface of the second through-post and a side surface and a lower surface of the second semiconductor chip.

9. The semiconductor package of claim 1, further comprising:
an external connection terminal and a passive device on a lower surface of the first redistribution substrate.

10. The semiconductor package of claim 1, wherein
the first semiconductor chip and the second semiconductor chip include logic chips, and
the semiconductor device includes a memory chip or memory package.

11. A semiconductor package comprising:
a first redistribution substrate having a first side and a second side spaced apart in a first horizontal direction;
a first semiconductor chip on the first side of the first redistribution substrate;
a first through-post on the second side of the first redistribution substrate;
a second through-post on the first semiconductor chip;
a second semiconductor chip on the first through-post;
a second redistribution substrate on the second semiconductor chip and the second through-post, the second redistribution substrate having a first side and a second side spaced apart in the first horizontal direction, the first side of the second redistribution substrate and the first side of the first redistribution substrate are aligned in a vertical direction perpendicular to an upper surface of the first redistribution substrate;
a heat dissipation block on the second side of the second redistribution substrate;
a semiconductor device on the first side of the second redistribution substrate;
a sealant located between the first redistribution substrate and the second redistribution substrate and covering side surfaces of the first through-post and the second through-post, a side surface and an upper surface of the first semiconductor chip, and a side surface and a lower surface of the second semiconductor chip; and
an external connection terminal on a lower surface of the first redistribution substrate.

12. The semiconductor package of claim 11, wherein
the first semiconductor chip at least partially overlaps the second semiconductor chip in the vertical direction perpendicular to the upper surface of the first redistribution substrate, and
the heat dissipation block overlaps the second semiconductor chip in the vertical direction.

13. The semiconductor package of claim 11, wherein
the first semiconductor chip and the second semiconductor chip each include an overlap region in which portions of the first semiconductor chip and the second semiconductor chip overlap each other in the vertical direction perpendicular to the upper surface of the first redistribution substrate,
an upper surface of the first semiconductor chip is an active surface, and the lower surface of the second semiconductor chip is an active surface, and
the first semiconductor chip is coupled to the second semiconductor chip so that the active surfaces face each other in the overlap region.

14. The semiconductor package of claim 11, wherein
the first semiconductor chip and the second semiconductor chip each include an overlap region in which portions of the first semiconductor chip and the second semiconductor chip overlap each other in the vertical direction perpendicular to the upper surface of the first redistribution substrate,
the first semiconductor chip includes a through-electrode therein,
a lower surface of the first semiconductor chip is an active surface and the lower surface of the second semiconductor chip is an active surface,
the first semiconductor chip is coupled to the second semiconductor chip so that an inactive surface of the first semiconductor chip faces the active surface of the second semiconductor chip in the overlap region, and
an active layer of the first semiconductor chip is connected to an active layer of the second semiconductor chip through the through-electrode.

15. The semiconductor package of claim 11, wherein
the first semiconductor chip and the second semiconductor chip include application processor chips, and
the semiconductor device includes a high bandwidth memory package.

16. A semiconductor package comprising:
a first redistribution substrate having a first side and a second side spaced apart in a first horizontal direction;
a first semiconductor chip on the first side of the first redistribution substrate;
a first through-post on the second side of the first redistribution substrate;
a second through-post on the first semiconductor chip;
a second semiconductor chip on the first through-post;
a second redistribution substrate on the second semiconductor chip and the second through-post, the second redistribution substrate having a first side and a second side spaced apart in the first horizontal direction, the first side of the second redistribution substrate and the first side of the first redistribution substrate are aligned in a vertical direction perpendicular to an upper surface of the first redistribution substrate;
a heat dissipation block on the second side of the second redistribution substrate;
a semiconductor device on the first side of the second redistribution substrate; and
a sealant located between the first redistribution substrate and the second redistribution substrate.

17. The semiconductor package of claim 16, wherein
the first semiconductor chip and the second semiconductor chip each include an overlap region in which portions of the first semiconductor chip and the second semiconductor chip overlap each other in the vertical direction perpendicular to the upper surface of the first redistribution substrate,
an upper surface of the first semiconductor chip is an active surface, and a lower surface of the second semiconductor chip is an active surface, and
the first semiconductor chip is coupled to the second semiconductor chip so that the active surfaces face each other in the overlap region.

18. The semiconductor package of claim 17, further comprising:
an intermediate redistribution substrate on the first semiconductor chip and the first through-post, the intermediate redistribution substrate having a first side and a second side spaced apart in the first horizontal direction, the first side of the intermediate redistribution substrate vertically aligned with the first side of the first redistribution substrate and the second redistribution substrate,
wherein the second semiconductor chip is on the second side of the intermediate redistribution substrate,
the second through-post is on the first side of the intermediate redistribution substrate,
the sealant is divided into a lower sealant below the intermediate redistribution substrate and an upper sealant above the intermediate redistribution substrate, and
the active surfaces of the first semiconductor chip and the second semiconductor chip face each other with the intermediate redistribution substrate therebetween in the overlap region.

19. The semiconductor package of claim 16, wherein
the first semiconductor chip and the second semiconductor chip each include an overlap region in which portions of the first semiconductor chip and the second semiconductor chip overlap each other in the vertical direction perpendicular to the upper surface of the first redistribution substrate,
the first semiconductor chip includes a through-electrode therein,
a lower surface of the first semiconductor chip is an active surface, and a lower surface of the second semiconductor chip is an active surface,
the first semiconductor chip is coupled to the second semiconductor chip so that an inactive surface of the first semiconductor chip faces the active surface of the second semiconductor chip in the overlap region, and
an active layer of the first semiconductor chip is connected to an active layer of the second semiconductor chip through the through-electrode.

20. The semiconductor package of claim 19, further comprising:
an intermediate redistribution substrate on the first semiconductor chip and the first through-post, the intermediate redistribution substrate having a first side and a second side spaced apart in the first horizontal direction, the first side of the intermediate redistribution substrate vertically aligned with the first side of the first redistribution substrate and the second redistribution substrate
the second semiconductor chip is on the second side of the intermediate redistribution substrate,
the second through-post is on the first side of the intermediate redistribution substrate,
the sealant is divided into a lower sealant below the intermediate redistribution substrate and an upper sealant above the intermediate redistribution substrate,
the inactive surface of the first semiconductor chip faces the active surface of the second semiconductor chip with the intermediate redistribution substrate therebetween in the overlap region, and
the active layer of the first semiconductor chip is connected to the active layer of the second semiconductor chip through the through-electrode and the intermediate redistribution substrate.

21-25. (canceled)
